(19) United States
(12) Patent Application Publication
(10) Pub. No.: US 2012/0001190 A1
(43) Pub. Date: Jan. 5, 2012

(54) THIN FILM TRANSISTOR AND METHOD OF FABRICATING SAME

(75) Inventors: Tohru Okabe, Osaka-shi (JP); Takeshi Yaneda, Osaka-shi (JP); Tetsuya Aita, Osaka-shi (JP); Tsuyoshi Inoue, Osaka-shi (JP); Yoshiyuki Harumoto, Osaka-shi (JP)

(73) Assignee: Sharp Kabushiki Kaisha, Osaka-shi, Osaka (JP)

(21) Appl. No.: 13/259,154

(22) PCT Filed: Feb. 9, 2010
(86) PCT No.: PCT/JP2010/051843

§ 371 Date: Sep. 23, 2011

(30) Foreign Application Priority Data
May 12, 2009 (JP) 2009-115112

(51) Int. Cl. H01L 29/786; H01L 21/336

(52) U.S. Cl. 257/66; 438/158; 257/E29.294; 257/E21.414

(57) ABSTRACT

The invention provides a thin film transistor that can improve its operating speed by improving crystallinity near a bottom surface of a channel layer. Of laser light irradiated onto an amorphous silicon layer, light transmitted through the amorphous silicon layer is absorbed by a gate electrode 130 and thereby produces heat. Since the gate electrode 130 is made of a titanium layer 102 with a low thermal conductivity, the produced heat is less likely to be transmitted through a gate wiring line 110 and dissipated and thus increases the temperature of the gate electrode 130. Radiant heat from the gate electrode 130 is provided to a bottom surface of the amorphous silicon layer and thus the amorphous silicon layer is also heated from its bottom surface. As a result, an amorphous silicon layer 106a melts not only from its top surface but also from its bottom surface and is solidified, whereby crystallization proceeds, and thus, the amorphous silicon layer 106a turns into a polycrystalline silicon layer 106b. Hence, the mobility near a bottom surface of the polycrystalline silicon layer 106b also increases, improving the operating speed of a thin film transistor 100.

### TECHNICAL FIELD

The present invention relates to a thin film transistor and a method of fabricating the thin film transistor, and more particularly to a bottom-gate type thin film transistor and a method of fabricating the bottom-gate type thin film transistor.

### BACKGROUND ART

A Thin Film Transistor (hereinafter, abbreviated as a TFT) having a channel layer made of an amorphous silicon layer is used as a switching element in a pixel formation portion of an active matrix-type liquid crystal display device. In recent years, an increase in the definition of liquid crystal display devices has progressed and thus the size of pixel formation portions has become smaller. Accordingly, there have also been demands for TFTs to reduce the areas occupied thereby and to reduce on-resistance in order to charge the pixel capacitances of the pixel formation portions in a short time. To meet these demands, a polycrystalline silicon layer having higher field-effect mobility (hereinafter, referred to as “mobility”) has started to be formed as a channel layer of a TFT, instead of an amorphous silicon layer.

As one of the methods for forming a polycrystalline silicon layer as a channel layer of a TFT, there is a laser annealing method. The laser annealing method is a crystallization method in which an amorphous silicon layer formed on a glass substrate is laser annealed for melting and is thereafter cooled for solidification. In the laser annealing method, since there is no need to heat the whole substrate to a high temperature, there is a feature that a low-cost glass can be used as a substrate.

For a technique related to this, Patent Document 1 discloses a technique in which a light-heat conversion layer is formed on a surface of a channel layer made of an amorphous silicon layer, with a buffer layer therebetween, and irradiated laser light is converted to heat by the light-heat conversion layer, thereby improving the crystallinity of the channel layer.

### PRIOR ART DOCUMENTS

### Patent Documents

[Patent Document 1] Japanese Patent Application Laid-Open No. 2007-5508

### SUMMARY OF THE INVENTION

### Problems to be Solved by the Invention

In a bottom-gate type TFT, laser light irradiated onto an amorphous silicon layer serving as a channel layer is irradiated onto a top surface of the amorphous silicon layer. The amorphous silicon layer absorbs the irradiated laser light and thereby produces heat and melts by the produced heat. Crystallization of the molten amorphous silicon layer proceeds upon cooling, whereby the layer turns into a polycrystalline silicon layer. Hence, the crystallinity of the polycrystalline silicon layer is highest near its top surface onto which the laser light is irradiated, and is lowest near its bottom surface (a surface on the side opposing a gate electrode). That is, the grain size of grains contained in the polycrystalline silicon layer is largest near the top surface of the channel layer and decreases as getting closer to its bottom surface, and is smallest near its bottom surface. The smaller the grain size of the polycrystalline silicon layer, the larger the number of gain boundaries that scatter electrons which are carriers, and thus, the mobility also decreases. In particular, in the bottom-gate type TFT, since the grain size grains contained in a portion of the polycrystalline silicon layer where a channel is formed, near its bottom surface opposing the gate electrode is small, the mobility near its bottom surface is low, causing a problem that the operating speed of the TFT cannot be improved.

In addition, the laser light irradiated onto the channel layer is absorbed at an absorption rate which is determined by the wavelength thereof and the material and film thickness of the channel layer. A portion of the laser light that is not absorbed is transmitted through the channel layer and is absorbed by the gate electrode and is thereby converted to heat. On the other hand, a gate electrode of a TFT and a gate wiring line electrically connected to the gate electrode each include a layer made of a metal with a high electrical conductivity such as aluminum (Al), copper (Cu), or silver (Ag), to prevent delay of a scanning signal. Since a metal with a high electrical conductivity also has a high thermal conductivity, heat produced in the gate electrode is transmitted through the gate wiring line and dissipated. Hence, to increase the crystallinity of a portion of the channel layer near its bottom surface by irradiating laser light onto the top surface of the channel layer, taking into account the heat transmitted through the gate wiring line and dissipated, there is a need to use a high-output laser device. However, since such a high-output laser device is costly, there is a problem of an increase in the fabrication cost of a thin film transistor.

In a bottom-gate type TFT described in Patent Document 1, a part of irradiated laser light is reflected by the light-heat conversion layer and thus does not contribute to crystallization. Hence, taking also into account laser light to be reflected, a high-output laser device is required. In addition, there is a need to add a step of forming a buffer layer and a light-heat conversion layer and a step of removing those layers after laser annealing. Due to them, there is a problem of an increase in the fabrication cost of a thin film transistor. Furthermore, since the light-heat conversion layer becomes a high temperature by absorbing laser light, impurities may diffuse into the amorphous silicon layer from the high-temperature light-heat conversion layer, which may adversely affect the electrical characteristics of the TFT.

An object of the present invention is therefore to provide a thin film transistor capable of improving its operating speed by improving the crystallinity of a portion of a channel layer near its bottom surface. Another object of the present invention is to provide a fabrication method capable of fabricating such a thin film transistor at low cost.

### Means for Solving the Problems

A first invention comprises:

a gate electrode formed on an insulating substrate;

a gate insulating film deposited to cover the insulating substrate having formed thereon the gate electrode;

a channel layer made of a polycrystalline semiconductor layer and formed above the gate electrode with the gate insulating film therebetween, the polycrystalline semiconductor layer being crystallized by irradiating laser light onto an amorphous semiconductor layer; and

a source electrode and a drain electrode formed above the channel layer so as to be overlaid on respective top surfaces of both edges of the channel layer, and

at least a surface of the gate electrode is made of a material that allows crystallization of the amorphous semiconductor layer from its bottom surface using the laser light.

A second invention is such that in the first invention

the gate electrode includes a metal that absorbs a portion of the laser light transmitted through the amorphous semiconductor layer and thereby produces radiant heat that allows crystallization of the amorphous semiconductor layer from its bottom surface.

A third invention is such that in the second invention

the gate electrode includes a metal with a thermal conductivity of 138 W/m·K or less.

A fourth invention is such that in the second invention

the gate electrode includes titanium or molybdenum.

A fifth invention is such that in the first invention

at least the surface of the gate electrode is made of a metal that reflects a portion of the laser light transmitted through the amorphous semiconductor layer, as light with an intensity at which crystallization of the amorphous semiconductor layer from its bottom surface is allowed.

A sixth invention is such that in the fifth invention

at least the surface of the gate electrode is made of a metal with a light reflectivity of 80% or more.

A seventh invention is such that in the fifth invention

at least the surface of the gate electrode is made of any one of aluminum, copper, and silver.

An eighth invention is such that in the first invention

the gate electrode is made of a transparent metal.

A ninth invention is such that in the sixth invention

the gate electrode includes a first layer; and a second layer formed to be located lower than the first layer, and having a larger width than the first layer,

the first layer is made of a metal with a light reflectivity of 80% or more, and

the second layer is made of a metal with a lower light reflectivity than the first layer, and protruding to left and right of the first layer in a planar view.

A tenth invention is directed to a method of fabricating a thin film transistor, the method comprising:

a gate electrode forming step of forming a gate electrode on an insulating substrate;

a gate insulating film forming step of forming a gate insulating film to cover the insulating substrate having formed thereon the gate electrode;

a laser annealing step of forming an amorphous semiconductor layer on the gate insulating film and irradiating laser light onto the amorphous semiconductor layer to turn the amorphous semiconductor layer into a polycrystalline semiconductor layer;

a channel layer forming step of forming a channel layer made of the polycrystalline semiconductor layer; and

an electrode forming step of forming a source electrode and a drain electrode formed above the channel layer so as to be overlaid on respective top surfaces of both edges of the channel layer, wherein

a wavelength of the laser light is 400 to 800 nm, and

in the laser annealing step, the amorphous semiconductor layer is crystallized from its top surface by being irradiated with the laser light and, at the same time, is crystallized from its bottom surface using a portion of the laser light transmitted through the amorphous semiconductor layer.

An eleventh invention is such that in the tenth invention

the gate electrode is formed using a metal with a thermal conductivity of 138 W/m·K or less.

A twelfth invention is such that in the tenth invention

the gate electrode is formed using a metal with a light reflectivity of 80% or more.

A thirteenth invention is such that in the twelfth invention

at least a surface of the gate electrode is made of copper, and

the wavelength of the laser light is 600 to 800 nm.

A fourteenth invention is such that in the tenth invention

the thin film transistor further includes a gate wiring line connected to the gate electrode, and

the gate electrode forming step includes:
a depositing step of depositing a stacked film made of a plurality of layers including a first layer made of a metal with a light reflectivity of 80% or more;
a resist film forming step of forming a resist film on a surface of the stacked film;
a pattern forming step of forming at least a first resist pattern and a second resist pattern by performing exposure using a first half-tone mask, the first resist pattern corresponding to a pattern of the gate electrode and the second resist pattern corresponding to a pattern of the gate wiring line and having a larger film thickness than the first resist pattern;
a first etching step of etching the stacked film using the first resist pattern and the second resist pattern as masks, thereby forming a stacked element which is to become the gate electrode, and the gate wiring line;
a first pattern removing step of removing the first resist pattern by oxygen plasma;
a second etching step of etching the stacked element in turn from its surface using the second resist pattern as a mask, until a surface of the first layer is exposed; and
a second pattern removing step of removing the second resist pattern.

A fifteenth invention is such that in the fourteenth invention

the stacked film includes a second layer located lower than the first layer and made of a metal with a lower light reflectivity than the first layer,

in the pattern forming step, the second resist pattern corresponding to the pattern of the gate wiring line, a third resist pattern, and fourth resist patterns are formed using a second half-tone mask, the third resist pattern corresponding to a central portion of the pattern of the gate electrode and having a smaller film thickness than the second resist pattern, and the fourth resist patterns sandwiching the third resist pattern and having a smaller film thickness than the third resist pattern, and

the second etching step includes:
a third pattern removing step of removing the fourth resist patterns by oxygen plasma;
a third etching step of performing etching in turn using the second resist pattern and the third resist pattern as masks, until a surface of the second layer of the stacked element which is to become the gate electrode is exposed;
a fourth pattern removing step of removing the third resist pattern by oxygen plasma; and
a fourth etching step of performing etching in turn using the second resist pattern as a mask, until the surface of the first layer of the stacked element which is to become the gate electrode is exposed.

### Effect of the Invention

According to the first invention, at least a surface of a gate electrode of a thin film transistor is made of a material that allows crystallization of an amorphous semiconductor layer from its bottom surface when the material is irradiated with laser light, by using the irradiated laser light. Accordingly, the amorphous semiconductor layer melts from its bottom surface and is crystallized. Therefore, in a polycrystalline semiconductor layer obtained by crystallizing the amorphous semiconductor layer, the grain size of grains contained in a portion of the polycrystalline semiconductor layer near its bottom surface increases and accordingly the mobility near its bottom surface increases. As such, since the mobility near the bottom surface of the polycrystalline semiconductor layer which is on the gate electrode side increases, the operating speed of the thin film transistor can be improved.

According to the second invention, of laser light irradiated onto the amorphous semiconductor layer, a portion of the laser light absorbed by the amorphous semiconductor layer crystallizes the amorphous semiconductor layer from its top surface. In addition, apart of laser light transmitted through the amorphous semiconductor layer is absorbed by the gate electrode and is thereby converted to heat, and the produced heat heats the bottom surface of the amorphous semiconductor layer. As a result, the amorphous semiconductor layer melts not only from its top surface but also from its bottom surface and is crystallized. Therefore, the grain size of grains contained in a portion of the polycrystalline semiconductor layer near its bottom surface increases and thus the mobility near its bottom surface also increases. As such, since the mobility near the bottom surface of the polycrystalline semiconductor layer increases, the operating speed of the thin film transistor can be improved.

According to the third invention, since the thermal conductivity of a metal forming the gate electrode is as low as 138 W/m·K, heat produced by absorbing laser light is less likely to be dissipated from the gate electrode by heat conduction, and accordingly, the temperature of the gate electrode increases. By radiant heat from such a gate electrode, the bottom surface of the amorphous semiconductor layer is heated and thus the same effect as that obtained by the second invention is provided.

According to the fourth invention, since the gate electrode includes titanium or molybdenum with a low thermal conductivity, heat produced by absorbing laser light is less likely to be dissipated from the gate electrode by heat conduction, and accordingly, the temperature of the gate electrode increases. By radiant heat from such a gate electrode, the bottom surface of the amorphous semiconductor layer is heated and thus the same effect as that obtained by the second invention is provided.

According to the fifth invention, at least the surface of the gate electrode is formed of a metal with a high light reflectivity. Hence, of laser light irradiated onto the amorphous semiconductor layer, most of laser light transmitted through the amorphous semiconductor layer is reflected by the surface of the gate electrode and is thereby irradiated onto the bottom surface of the amorphous semiconductor layer. As such, since the amorphous semiconductor layer is irradiated with laser light not only from its top surface but also from its bottom surface, a portion of the amorphous semiconductor layer near its bottom surface also melts and is crystallized. As a result, in a polycrystalline semiconductor layer obtained by crystallizing the amorphous semiconductor layer, the grain size of grains contained not only in a portion of the polycrystalline semiconductor layer near its top surface but also in a portion of the polycrystalline semiconductor layer near its bottom surface increases and accordingly the mobility near its bottom surface also increases. As such, since the mobility near the bottom surface of the polycrystalline semiconductor layer increases, the operating speed of the thin film transistor can be improved.

According to the sixth invention, at least the surface of the gate electrode is made of a metal with a light reflectivity of 80% or more. Such a gate electrode reflects, at its surface, most of laser light transmitted through the amorphous semiconductor layer, and the reflected laser light is irradiated onto the bottom surface of the amorphous semiconductor layer. Accordingly, the sixth invention has the same effect as that obtained by the fifth invention.

According to the seventh invention, the surface of the gate electrode is made of any one of aluminum, silver, and copper with a light reflectivity of 80% or more. Such a gate electrode reflects, at its surface, most of laser light transmitted through the amorphous semiconductor layer, and the reflected laser light is irradiated onto the bottom surface of the amorphous semiconductor layer. Accordingly, the same effect as that obtained by the fifth invention is provided.

According to the eighth invention, since the thin film transistor has the gate electrode made of a transparent metal, laser light can be directly irradiated onto the bottom surface of the amorphous semiconductor layer from the insulating substrate side. When laser light is irradiated from the insulating substrate side, the laser light is transmitted through the gate electrode and is irradiated onto the bottom surface of the amorphous semiconductor layer, whereby the amorphous semiconductor layer melts from its bottom surface, turning into a polycrystalline semiconductor layer. Therefore, the grain size near the bottom surface of the polycrystalline semiconductor layer is larger than that near the top surface thereof and accordingly the mobility near the bottom surface increases, enabling to improve the operating speed of the thin film transistor.

According to the ninth invention, in the thin film transistor, a channel layer with a low resistance value and offset regions with a high resistance value which sandwich the channel layer are formed. Namely, of laser light transmitted through the amorphous semiconductor layer, the intensity of a portion of the laser light reflected by a first layer of the gate electrode whose light reflectivity is 80% or more is strong. In this case, the reflected laser light is irradiated onto the bottom surface of a portion of the amorphous semiconductor layer immediately above the first layer, thereby melting a portion of the amorphous semiconductor layer near its bottom surface. Hence, in a portion of a polycrystalline semiconductor layer immediately above the first layer, the grain size not only near its top surface but also near its bottom surface increases, and thus, the portion turns into a channel region with a low resistance value. On the other hand, the intensity of laser light reflected by a second layer protruding from the first layer of the gate electrode is weak. Thus, the grain size near the bottom surfaces of those portions of the polycrystalline semiconductor layer immediately above the protruding second layer decreases, and thus, the portions turn into offset regions with a high resistance value. Such a thin film transistor decreases leakage current flowing when in an off state, enabling to increase the on/off ratio. In addition, since the offset regions are formed immediately above the second layer in a self-aligned manner, there is no need to perform layout taking into account misalignment. Accordingly, the area occupied by the thin film transistor can be reduced.

According to the tenth invention, when laser light with a wavelength of 400 to 800 nm is irradiated onto the amorphous semiconductor layer from above, the laser light is absorbed by the amorphous semiconductor layer at a predetermined absorption rate which is determined by the wavelength thereof and the material and film thickness of the amorphous semiconductor layer, and the absorbed laser light crystallizes the amorphous semiconductor layer from its top surface. In addition, a portion of the laser light transmitted through the amorphous semiconductor layer is irradiated onto the gate electrode. At least the surface of the gate electrode is made of a material that allows crystallization of the bottom surface of the amorphous semiconductor layer by using the irradiated laser light. Hence, the amorphous semiconductor layer melts not only from its top surface but also from its bottom surface and is crystallized. In a polycrystalline semiconductor layer crystallized in such a manner, the grain size not only near its top surface but also near its bottom surface can be increased, enabling to fabricate a thin film transistor in which the mobility near the bottom surface of the polycrystalline semiconductor layer is high.

According to the eleventh invention, since the thermal conductivity of a metal forming the gate electrode is as low as 138 W/m·K, heat produced by laser light absorbed by the gate electrode is less likely to be dissipated from the gate electrode by heat conduction, and accordingly, the temperature of the gate electrode increases. In addition, since the gate electrode is made of a metal, apart of laser light transmitted through the amorphous semiconductor layer is reflected by the gate electrode and is thereby irradiated onto the bottom surface of the amorphous semiconductor layer. By radiant heat from such a gate electrode and light reflected by the gate electrode, the bottom surface of the amorphous semiconductor layer is heated, and accordingly, the amorphous semiconductor layer also melts from its bottom surface and is crystallized. In a polycrystalline semiconductor layer crystallized in such a manner, the grain size not only near its top surface but also near its bottom surface can be increased, enabling to fabricate a thin film transistor in which the mobility near the bottom surface of the polycrystalline semiconductor layer is high.

According to the twelfth invention, since at least the surface of the gate electrode is made of a metal with a light reflectivity of 80% or more, most of laser light transmitted through the amorphous semiconductor layer is reflected by the surface of the gate electrode and is thereby irradiated onto the bottom surface of the amorphous semiconductor layer. The amorphous semiconductor layer is heated by absorbing the laser light irradiated onto its bottom surface and thus is also crystallized from its bottom surface. In a polycrystalline semiconductor layer crystallized in such a manner, the grain size not only near its top surface but also near its bottom surface increases, enabling to fabricate a thin film transistor in which the mobility near the bottom surface of the polycrystalline semiconductor layer is high.

According to the thirteenth invention, the reflectivity of copper is 90% or more with respect to light with a wavelength of 600 to 800 nm. Hence, by irradiating laser light with a long wavelength such as a wavelength of 600 to 800 nm onto the amorphous semiconductor layer, most of the irradiated laser light is transmitted through the amorphous semiconductor layer and is irradiated onto the gate electrode. Since at least the surface of the gate electrode is made of copper, most of the laser light transmitted through the amorphous semiconductor layer is further reflected by the surface of the gate electrode and is thereby irradiated onto the bottom surface of the amorphous semiconductor layer. As such, when at least the surface of the gate electrode is formed of copper, laser light with high energy is irradiated onto the bottom surface of the amorphous semiconductor layer, enabling to form a polycrystalline semiconductor layer having higher crystallinity at its bottom surface. In addition, since a laser device that oscillates laser light with a long wavelength is inexpensive and is easy for maintenance, the fabrication cost of a thin film transistor can be reduced.

According to the fourteenth invention, by using a first half-tone mask, the film thickness of a first resist pattern formed in a region where a gate electrode is to be formed can be made thinner than the film thickness of a second resist pattern formed in a region where a gate wiring line is to be formed. By performing etching using such a first resist pattern and a second resist pattern as masks, a gate wiring line and a stacked element which is to become a gate electrode are formed. Then, only the first resist pattern is removed using oxygen plasma and the stacked element which is to become a gate electrode is etched in turn from its top surface until a surface of a first layer made of a metal with a light reflectivity of 80% or more is exposed. As such, since etching is performed twice using, as masks, resist patterns formed in a single photolithographic process, the steps of fabricating a thin film transistor can be simplified, enabling to reduce fabrication cost. In addition, since the first resist pattern and the second resist pattern are simultaneously formed and unnecessary resist patterns are removed in turn, there is no need to perform layout taking into account their misalignment, enabling to reduce the area occupied by the thin film transistor.

According to the fifteenth invention, by using a second half-tone mask, a third resist pattern is formed at a central portion of a stacked element which is to become a gate electrode, and fourth resist patterns having a smaller film thickness than the third resist pattern are formed at left and right edges sandwiching the central portion of the stacked element which is to become a gate electrode. Then, only the fourth resist patterns are removed by oxygen plasma and the stacked element which a gate electrode is etched until a surface of a second layer is exposed. Then, the third resist pattern is removed by oxygen plasma to expose the central portion of the stacked element which is to become a gate electrode, and etching is performed until the first layer is exposed. In this case, since the second layer has a low light reflectivity, crystallization is insufficient at the bottom surfaces of those portions of the amorphous semiconductor layer opposing the left and right edges of the gate electrode, and thus, the portions turn into semiconductor layers with a high resistance value. On the other hand, since the first layer has a high light reflectivity, sufficient crystallization is performed at the bottom surface of a portion of the amorphous semiconductor layer opposing the central portion of the gate electrode, and thus, the portion turns into a polycrystalline semiconductor layer with a low resistance value. As such, since etching is performed twice using, as masks, resist patterns formed in a single photolithographic process, the steps of fabricating a thin film transistor having offset regions can be simplified. In addition, the semiconductor layers with a high resistance value are formed immediately above the second layer in a self-aligned manner so as to sandwich the polycrystalline semiconductor layer with a low resistance value, without forming a resist pattern. Hence, the step of forming a resist pattern is not required and thus the fabrication steps can be likewise simplified. When the steps of fabricating a thin film transistor can be thus simplified, the fabrication cost of a thin film transistor can be reduced. In addition, since the semiconductor layers with a high resistance value are formed without using a resist pattern, alignment upon formation of a resist pattern is not required and thus the layers are arranged with high accuracy. Furthermore, since the third resist pattern and the fourth resist patterns are simultaneously formed and unnecessary resist patterns are removed in turn, there is no need to perform layout taking into account their misalignment. Hence, the area occupied by the thin film transistor can be reduced.

### BRIEF DESCRIPTION OF THE DRAWINGS

FIG. 1 is a plan view showing a configuration of a pixel formation portion of a liquid crystal display device, which uses a TFT according to a first embodiment of the present invention as a switching element.

FIGS. 2A and 2B are cross-sectional views of the TFT according to the first embodiment of the present invention; more specifically, FIG. 2A is a cross-sectional view of the TFT and a gate wiring line taken along line A-A shown in FIG. 1, and FIG. 2B is a cross-sectional view of the TFT taken along line B-B shown in FIG. 1.

FIGS. 3A to 3C are cross-sectional views showing the steps of fabricating the TFT shown in FIGS. 2A and 2B which is connected to the gate wiring line in the pixel formation portion.

FIGS. 4D to 4F are cross-sectional views showing the steps of fabricating the TFT shown in FIGS. 2A and 2B which is connected to the gate wiring line in the pixel formation portion.

FIGS. 5G to 5I are cross-sectional views showing the steps of fabricating the TFT shown in FIGS. 2A and 2B which is connected to the gate wiring line in the pixel formation portion.

FIG. 6 is a graph showing a relationship between the transmittance of amorphous silicon and the wavelength of laser light.

FIGS. 7A and 7B are cross-sectional views of a TFT according to a second embodiment of the present invention; more specifically, FIG. 7A is a cross-sectional view of the TFT and a gate wiring line taken along line A-A shown in FIG. 1, and FIG. 7B is a cross-sectional view of the TFT taken along line B-B shown in FIG. 1.

FIGS. 8A to 8C are cross-sectional views showing the steps of fabricating the TFT shown in FIGS. 7A and 7B which is connected to the gate wiring line in a pixel formation portion.

FIGS. 9D to 9F are cross-sectional views showing the steps of fabricating the TFT shown in FIGS. 7A and 7B which is connected to the gate wiring line in the pixel formation portion.

FIGS. 10G and 10H are cross-sectional views showing the steps of fabricating the TFT shown in FIGS. 7A and 7B which is connected to the gate wiring line in the pixel formation portion.

FIGS. 11A and 11B are cross-sectional views of a TFT according to a third embodiment of the present invention; more specifically, FIG. 11A is a cross-sectional view of the TFT and a gate wiring line taken along line A-A shown in FIG. 1, and FIG. 11B is a cross-sectional view of the TFT taken along line B-B shown in FIG. 1.

FIGS. 12A to 12C are cross-sectional views showing the steps of fabricating the TFT shown in FIGS. 11A and 11B which is connected to the gate wiring line in a pixel formation portion.

FIGS. 13D to 13F are cross-sectional views showing the steps of fabricating the TFT shown in FIGS. 11A and 11B which is connected to the gate wiring line in the pixel formation portion.

FIGS. 14G to 14I are cross-sectional views showing the steps of fabricating the TFT shown in FIGS. 11A and 11B which is connected to the gate wiring line in the pixel formation portion.

FIGS. 15J and 15K are cross-sectional views showing the steps of fabricating the TFT shown in FIGS. 11A and 11B which is connected to the gate wiring line in the pixel formation portion.

FIGS. 16A and 16B are cross-sectional views of a TFT according to a first variant of the present invention; more specifically, FIG. 16A is a cross-sectional view of the TFT and a gate wiring line taken along line A-A shown in FIG. 1, and FIG. 16B is a cross-sectional view of the TFT taken along line B-B shown in FIG. 1.

### MODE FOR CARRYING OUT THE INVENTION

Embodiments of the present invention will be described in detail below based on the drawings.

### 1. First Embodiment

### 1.1 Configuration of a Pixel Formation Portion

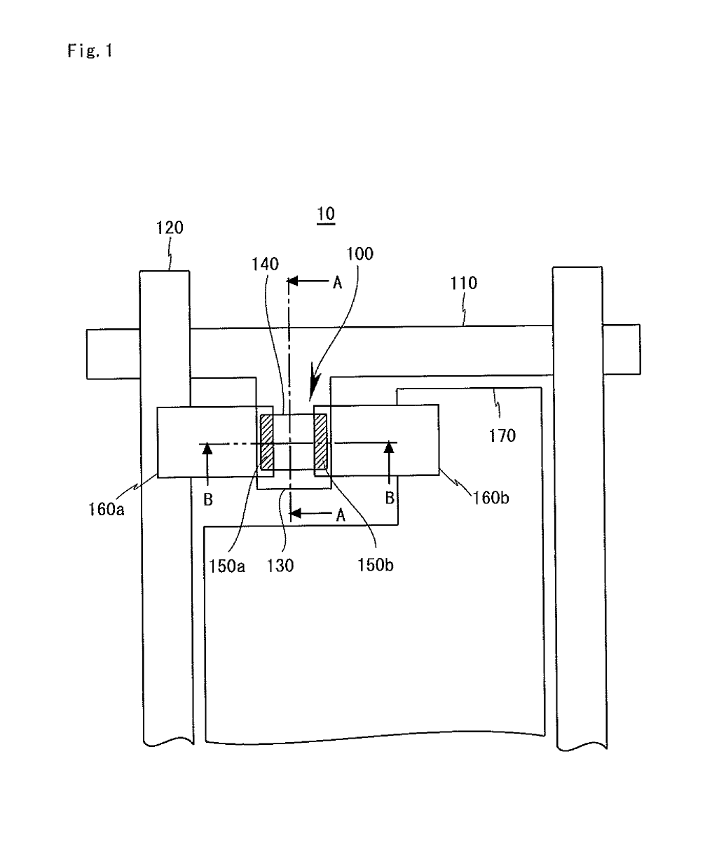

FIG. 1 is a plan view showing a configuration of a pixel formation portion 10 of a liquid crystal display device, which uses a TFT 100 according to a first embodiment of the present invention as a switching element. As shown in FIG. 1, in the pixel formation portion 10, a gate wiring line 110 extending in a horizontal direction and a source wiring line 120 extending in a vertical direction are formed to intersect each other. A bottom-gate type TFT 100 is formed near an intersecting portion of the gate wiring line 110 and the source wiring line 120. Specifically, a gate electrode 130 branching from the gate wiring line 110 is formed, and a channel layer 140 made of a polycrystalline silicon layer is formed above the gate electrode 130.

A source electrode 160a is formed on the side of the source wiring line 120 (the left side in FIG. 1) of the gate electrode 130, and a drain electrode 160b is formed on the opposite side of the source electrode 160a (the right side in FIG. 1) of the gate electrode 130. The source electrode 160a is electrically connected to the channel layer 140 with a contact layer 150a therebetween, and is also electrically connected to the source wiring line 120. The drain electrode 160b is electrically connected to the channel layer 140 with a contact layer 150b therebetween, and is also electrically connected to a pixel electrode 170. When the TFT 100 is placed in an on state, a voltage according to an image signal is provided to the pixel electrode 170 from the source wiring line 120 through the TFT 100. The pixel electrode 170 forms a pixel capacitance together with a counter electrode (not shown) formed on a color filter substrate. The pixel capacitance holds a voltage according to image while the TFT 100 is in an off state.

### 1.2 Structure of the TFT

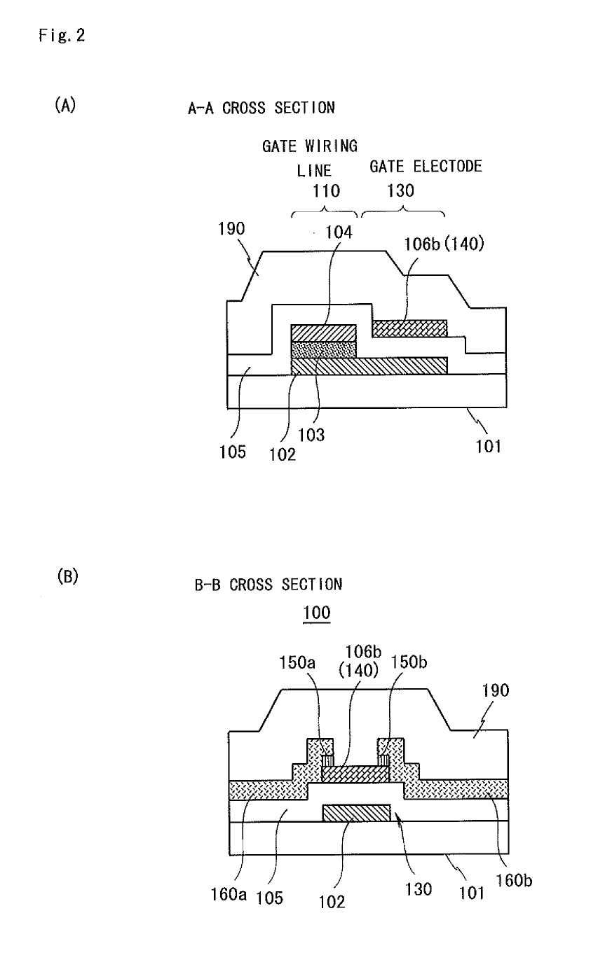

Next, the structures of the TFT 100 and the gate wiring line 110 electrically connected to the TFT 100 will be described. FIGS. 2A and 2B are cross-sectional views of the TFT 100. More specifically, FIG. 2A is a cross-sectional view of the TFT 100 and the gate wiring line 110 taken along line A-A shown in FIG. 1, and FIG. 2B is a cross-sectional view of the TFT 100 taken along line B-B.

As shown in FIGS. 2A and 2B, the gate wiring line 110 and the gate electrode 130 branching from the gate wiring line 110 are formed on a glass substrate 101. The gate wiring line 110 has a stacked structure in which a titanium (Ti) layer 102, an aluminum layer 103, and a titanium layer 104 are stacked in succession on a surface of the glass substrate 101. The gate electrode 130 has a single layer structure in which only the titanium layer 102 is formed on the surface of the glass substrate 101. The titanium layer 102 of the gate wiring line 110 and the titanium layer 102 of the gate electrode 130 are formed of the same titanium layer.

A silicon nitride (SiNx) film 105 functioning as a gate insulating film is formed to cover the gate electrode 130 and the gate wiring line 110. A non-doped polycrystalline silicon layer 106b functioning as the channel layer 140 is formed on a portion of the silicon nitride film 105 above the gate electrode 130.

The polycrystalline silicon layer 106b is formed by, as will be described later, crystallizing an amorphous silicon layer not only from its top surface but also from its bottom surface by laser annealing. Hence, in the polycrystalline silicon layer 106b, not only the grain size of grains near its top surface but also the grain size of grains near its bottom surface is sufficiently large.

The mobility of the polycrystalline silicon layer 106b has a close relationship with grain size. In particular, in an n-channel type TFT where electrons serve as majority carriers, the electrons are likely to be scattered at grain boundaries. Hence, when the grain size increases, the mobility of the polycrystalline silicon layer 106b increases, and thus, the operating speed of the TFT 100 having the polycrystalline silicon layer 106b as the channel layer 140 increases.

The contact layers 150a and 150b made of n⁺ silicon films containing high-concentration n-type impurities are respectively formed at the left and right top surface edges of the polycrystalline silicon layer 106b. Furthermore, the source electrode 160a extending to the left from the contact layer 150a and the drain electrode 160b extending to the right from the contact layer 150b are formed. The source electrode 160a and the drain electrode 160b are ohmic-connected to the polycrystalline silicon layer 106b through the contact layers 150a and 150b, respectively. In addition, both of the source electrode 160a and the drain electrode 160b are made of a stacked metal film in which an aluminum layer is stacked on a titanium layer.

The gate wiring line 110 and the TFT 100 are covered with a protective film 190 made of silicon nitride. Note that, though not shown in FIGS. 2A and 2B, the gate wiring line 110 and the TFT 100 are further covered with a planarizing film made of an acrylic resin, etc., and the pixel electrode 170 electrically connected to the drain electrode 160b is formed on a surface of the planarizing film.

### 1.3 Method of Fabricating the TFT

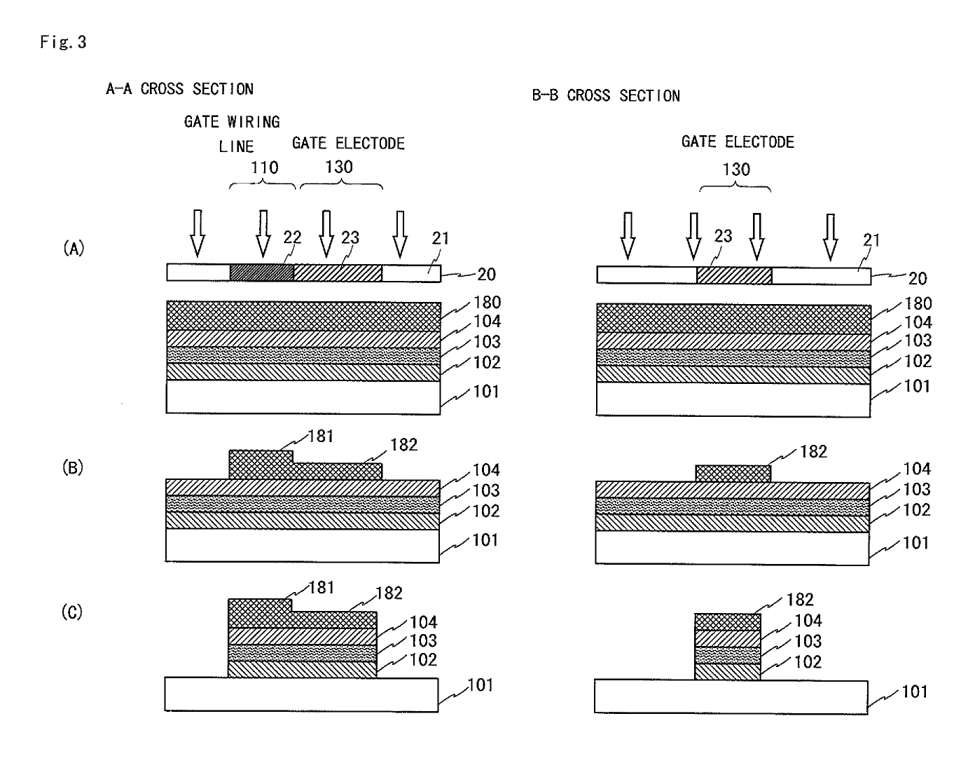

Next, a method of fabricating the TFT 100 will be described. FIGS. 3A to 3C to 5G to 5I are cross-sectional views showing the steps of fabricating the TFT 100 connected to the gate wiring line 110 in the pixel formation portion 10. The left diagrams in each figure are the same cross-sectional views as that of the TFT 100 and the gate wiring line 110 shown in FIG. 2A, and the right diagrams are the same cross-sectional views as that of the TFT 100 shown in FIG. 2B.

As shown in FIG. 3A, a titanium layer 102, an aluminum layer 103, and a titanium layer 104 are continuously deposited on a surface of a glass substrate 101 in this order from the side of the glass substrate 101 by a sputtering method. Their film thicknesses are, for example, such that the titanium layer 102 is 50 nm, the aluminum layer 103 is 200 nm, and the titanium layer 104 is 50 nm. Here, the titanium layer 102 which is a bottom layer is provided to obtain good adhesion to the glass substrate 101 to make it difficult to peel off. The titanium layer 104 which is a top layer is provided to ohmic-connect the gate wiring line 110 to an Indium Tin Oxide (hereinafter, abbreviated as “ITO”) in a peripheral contact area (not shown) provided in an outer portion of a display area of the liquid crystal display device. The aluminum layer 103 is provided to prevent delay of a scanning signal. Note that, instead of the aluminum layer 103, a layer made of copper or silver with a higher electrical conductivity than aluminum may be used.

Then, a photoresist film 180 is formed on a surface of the titanium layer 104 and is exposed using a half-tone mask having a predetermined pattern formed therein. The half-tone mask 20 includes a light-shielding region 22 having formed therein a light-shielding pattern which does not allow incident light to be transmitted therethrough at all; a transmission region 21 which allows incident light to be transmitted therethrough as it is; and a semi-transmission region 23 having formed therein a semi-transmission pattern which weakens the intensity of incident light and allows the incident light to be transmitted therethrough. The semi-transmission pattern is formed by a pattern made of a light-shielding film and having slits or dots arranged therein/on, to weaken the intensity of incident light.

In the half-tone mask 20, the pattern of the gate wiring line 110 is made of a light-shielding pattern and the pattern of the gate electrode 130 is made of a semi-transmission pattern, and a region where the titanium layer 102, the aluminum layer 103, and the titanium layer 104 are all removed corresponds to the transmission region 21. In this case, the film thickness of a resist pattern 182 in a region where the gate electrode 130 is to be formed is determined by the intensity of light which is transmitted through the semi-transmission pattern.

In the present embodiment, the transmittance of the semi-transmission region 23 is adjusted such that the intensity of light transmitted through the semi-transmission pattern is on the order of one-half of the intensity of light transmitted through the transmission region 21. Hence, by performing exposure using the half-tone mask 20 and development, as shown in FIG. 3B, the film thickness of the resist pattern 182 in the region where the gate electrode 130 is to be formed is on the order of one-half of the film thickness of a resist pattern 181 in a region where the gate wiring line 110 is to be formed.

As shown in FIG. 3C, using the resist patterns 181 and 182 as masks, etching is performed on the titanium layer 104, the aluminum layer 103, and the titanium layer 102 in this order by a dry etching method while changing gas. As a result, the gate wiring line 110 and the gate electrode 130 both have a stacked structure in which three layers, the titanium layer 102, the aluminum layer 103, and the titanium layer 104, are stacked on top of one another.

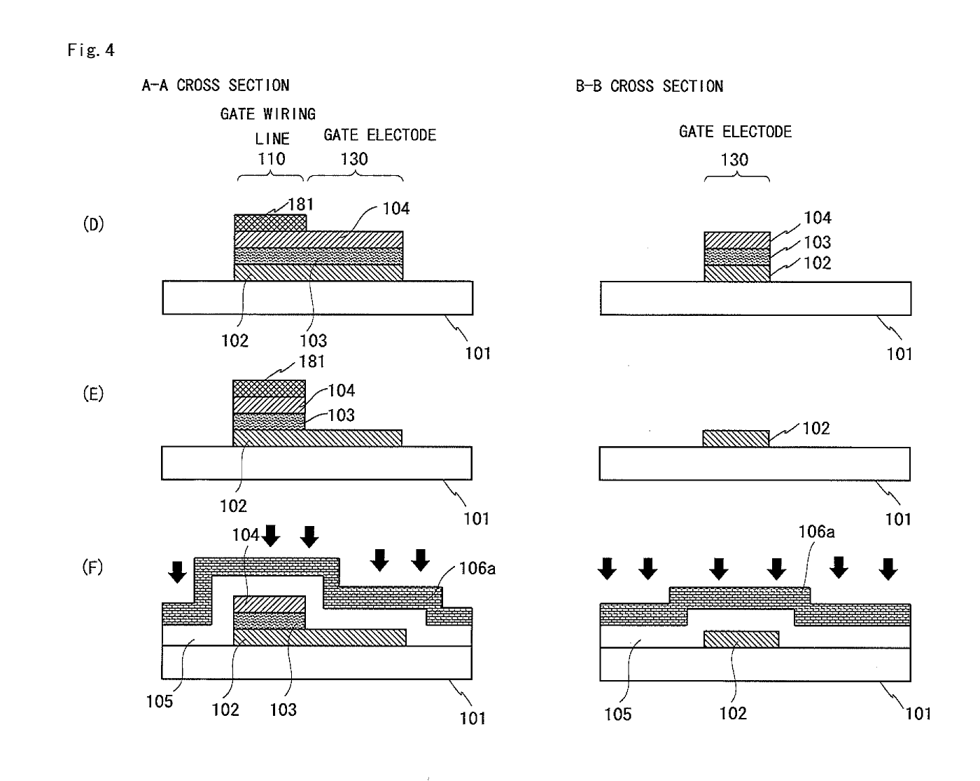

As shown in FIG. 4D, in order to expose a surface of the titanium layer 104 of the gate electrode 130, the resist pattern 182 is removed. The resist pattern 182 is removed by ashing using oxygen plasma. At this time, since a part of the resist pattern 181 on the gate wiring line 110 is also ashed, the film thickness of the resist pattern 181 is also reduced. However, since the resist pattern 181 is formed such that its film thickness has a thickness about twice the film thickness of the resist pattern 182, even after the resist pattern 182 on the gate electrode 130 is removed, the gate wiring line 110 is covered with the resist pattern 181.

As shown in FIG. 4E, using the resist pattern 181 as a mask, the titanium layer 104 of the gate electrode 130 is removed by etching. The etching is performed by wet etching in order to increase the ratio of the etch rates (selectivity) of the titanium layer 104 and the aluminum layer 103. Specifically, to etch the titanium layer 104, etching is performed using a hydrofluoric/nitric acid-based etchant containing hydrofluoric acid (HF) and nitric acid (HNO₃). To etch the aluminum layer 103, etching is performed using an acetic acid-based etchant containing acetic acid (CH₂COOH). At this time, since titanium does not dissolve in the acetic acid-based etchant almost at all, the film thickness of the titanium layer 102 remaining on the glass substrate 101 is substantially the same film thickness as that at the time of deposition. Then, the resist pattern 181 on the gate wiring line 110 is peeled off by oxygen plasma asking. As a result, the gate wiring line 110 has a stacked structure in which the titanium layer 102, the aluminum layer 103, and the titanium layer 104 are stacked on top of one another in this order from the side of the glass substrate 101, and the gate electrode 130 has a single layer structure including only the titanium layer 102.

As shown in FIG. 4F, a silicon nitride film 105 serving as a gate insulating film is deposited by Plasma Enhanced Chemical Vapor Deposition method (hereinafter, referred to as “plasma CVD method”) to cover the gate electrode 130 and the gate wiring line 110. The film thickness of the silicon nitride film 105 is, for example, 400 nm. Note that as the gate insulating film, instead of the silicon nitride film 105, a silicon dioxide (SiO₂) film or a stacked film of a silicon nitride film and a silicon dioxide film may be deposited.

Then, a non-doped amorphous silicon layer 106a is deposited on a surface of the silicon nitride film 105 by a plasma CVD method, for example, monosilane (SiH₄) or disilane (Si₂H₆) as a raw gas. The film thickness of the amorphous silicon layer 106a is, for example, 50 to 200 nm.

Laser light (green laser light) with a wavelength of 532 nm oscillated from a solid laser device is irradiated onto the amorphous silicon layer 106a. When the laser light is irradiated onto a top surface of the amorphous silicon layer 106a, the amorphous silicon layer 106a melts and is thereafter cooled and thereby crystallized, turning into a polycrystalline silicon layer 106b with grains being continuous. By this crystallization, the grain size of grains contained in a portion of the polycrystalline silicon layer 106b near its top surface is on the order of 10 to 300 nm.

At this time, when the energy density of laser light to be irradiated is low, crystal growth becomes insufficient and thus grain size decreases. Conversely, when the energy density is too high, the grains themselves are broken and thus microcrystals are likely to grow. Hence, there is a need to optimize the energy density of laser light. More specifically, laser light to be irradiated is a rectangular beam which is shaped such that the intensity profile on the long-axis side is of a flat top-hat type and the intensity profile on the short-axis side is of a Gaussian type, by allowing laser light oscillated from the solid laser device to pass through a microlens. The energy density of this rectangular beam is set to 220 to 360 mJ/cm² and the rectangular beam is scanned parallel to the glass substrate 101 at a rate of about 40 mm/sec.

Next, the wavelength of laser light to be irradiated will be described. When the wavelength of laser light is about 350 nm, the laser light starts to be transmitted through the amorphous silicon layer 106a, and in the vicinity of a wavelength of 532 nm, about 50% of laser light irradiated is absorbed by the amorphous silicon layer 106a, and the remaining about 50% is transmitted through the amorphous silicon layer 106a and the silicon nitride film 105 and is then irradiated onto the titanium layer 102 of the gate electrode 130. The titanium layer 102 absorbs about 50% of the energy of the irradiated laser light and converts it to heat. However, since the thermal conductivity of titanium is as low as 22 W/m·K, the heat produced in the titanium layer 102 is less likely to be transmitted through the aluminum layer 103 of the gate wiring line 110 and thus is accumulated in the titanium layer 102. Hence, the titanium layer 102 becomes a high temperature, and by radiant heat from the titanium layer 102, the bottom surface of the amorphous silicon layer 106a is heated.

The remaining 50% of the laser light irradiated onto the titanium layer 102 is reflected by the titanium layer 102 and is thereby irradiated onto the bottom surface of the amorphous silicon layer 106a. A part of the laser light irradiated onto the bottom surface of the amorphous silicon layer 106a is absorbed by the amorphous silicon layer 106a and is thereby converted to heat. As such, the amorphous silicon layer 106a is also heated from its bottom surface by the radiant heat which is provided from the titanium layer 102 of the gate electrode 130 and the heat produced by absorbing laser light reflected by the titanium layer 102. Therefore, crystallization also proceeds near the bottom surface of the amorphous silicon layer 106a and the grain size of grains contained in the polycrystalline silicon layer 106b increases.

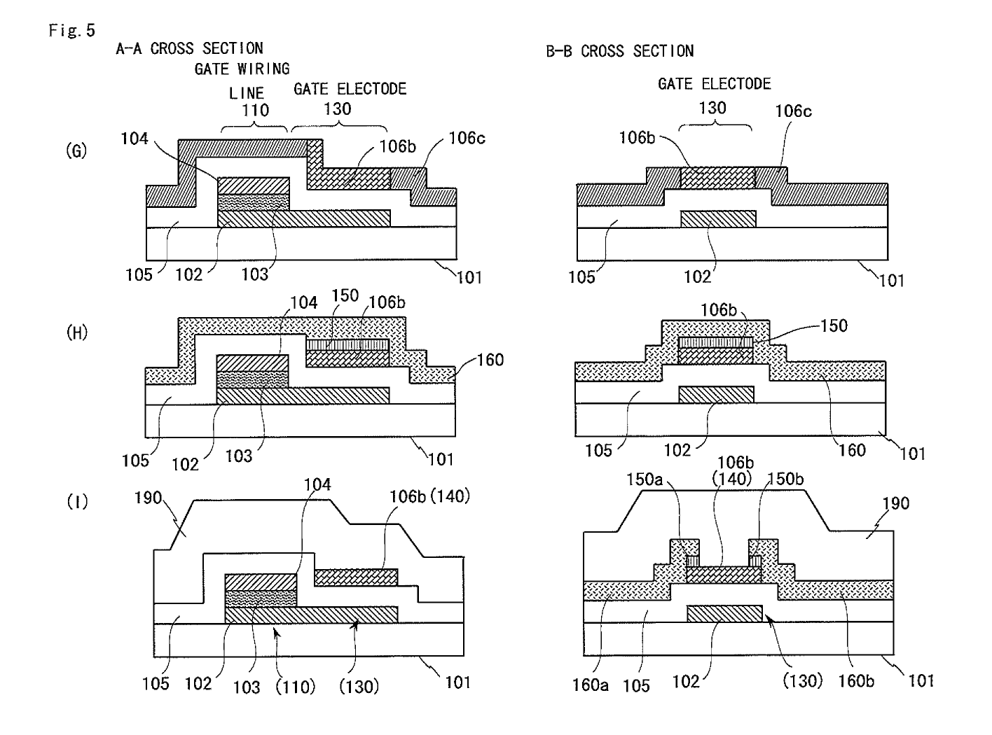

As shown in FIG. 5G, in a region of the amorphous silicon layer 106a under which the gate electrode 130 is provided, crystallization proceeds from both the top and bottom surfaces of the amorphous silicon layer 106a, and thus, the region turns into the polycrystalline silicon layer 106b in which the grain size of grains contained therein at its bottom surface is also large. On the other hand, in a region under which the gate electrode 130 is not provided, crystallization is performed only by laser light irradiated from the top surface, and thus, crystallization near the bottom surface is insufficient, and accordingly, it turns into a polycrystalline silicon layer 106c in which the grain size of grains contained therein near the bottom surface is smaller than that of grains contained therein near the top surface. In this case, the inventors of the present invention have obtained the electrical conductivities of the polycrystalline silicon layer 106b and the polycrystalline silicon layer 106c, and as a result, it has been found that the electrical conductivity of the polycrystalline silicon layer 106c is about two digits lower than the electrical conductivity of the polycrystalline silicon layer 106b.

Note that whether the amorphous silicon layer 106a turns into the polycrystalline silicon layer 106c is determined by the energy of laser light irradiated onto the amorphous silicon layer 106a. When the energy is low, the amorphous silicon layer 106a remains as an amorphous silicon layer or turns into a microcrystalline silicon layer. However, in either case, in the present embodiment, they are removed by etching which will be described later, and thus, there is no substantial influence. This is also the same for the case of a second embodiment which will be described later, and thus, description thereof is omitted in the second embodiment. Note that although the titanium layer 104 is also formed on a surface of the gate wiring line 110, since heat produced in the titanium layer 104 of the gate wiring line 110 is transmitted through the aluminum layer 103 and dissipated, it does not contribute to crystallization of the amorphous silicon layer 106a.

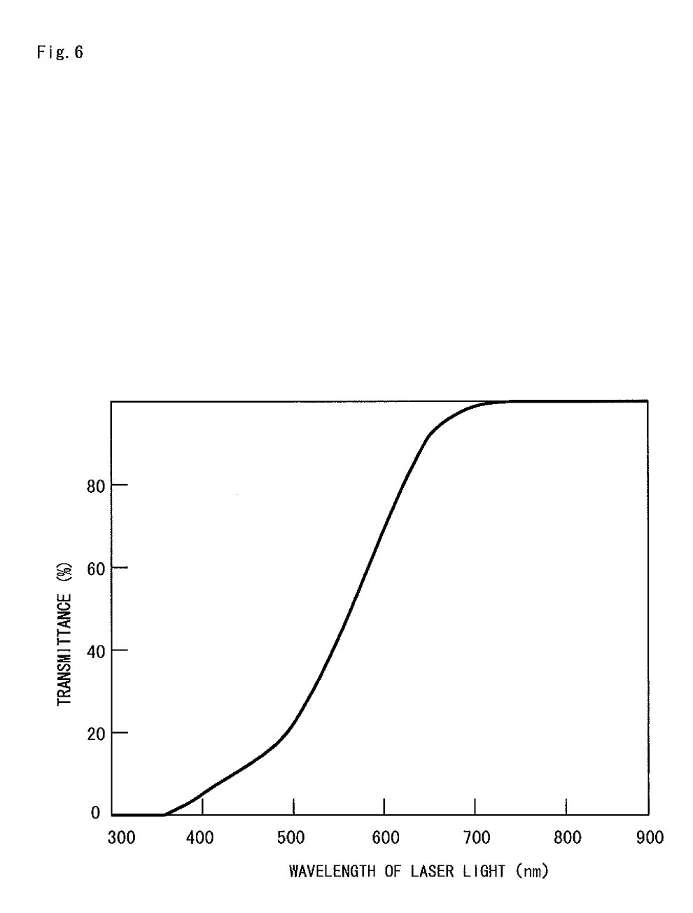

As described above, in the present embodiment, the wavelength of laser light is set to 532 nm so that about 50% of irradiated laser light can be absorbed by the amorphous silicon layer 106a and the remaining 50% can be transmitted through the amorphous silicon layer 106a. However, the wavelength of laser light usable in the present embodiment is not limited thereto and the wavelength can be any as long as a part of laser light to be irradiated is absorbed by the amorphous silicon layer 106a and the remainder is transmitted through the amorphous silicon layer 106a. FIG. 6 is a graph showing a relationship between the transmittance of amorphous silicon and the wavelength of laser light. As shown in FIG. 6, the laser light starts to be transmitted through the amorphous silicon in the vicinity of a wavelength of 350 nm and the transmittance is several % at a wavelength of 400 nm. The longer the wavelength of the laser light, the higher the transmittance, and the transmittance is substantially 100% at a wavelength of 800 nm. In the present embodiment, when several % or more of laser light is transmitted through the amorphous silicon layer 106a, the amorphous silicon layer 106a can be crystallized from its bottom surface using the transmitted laser light. Hence, the wavelength of laser light to be used should be 400 nm to 800 nm. This is also the same for the case of the second and third embodiments which will be described later, and thus, description thereof is omitted in the second and third embodiments.

Then, a resist pattern (not shown) is formed on the polycrystalline silicon layer 106b, and the polycrystalline silicon layer 106c is etched by a dry etching method, using the resist pattern as a mask. As a result, as shown in FIG. 5H, a channel layer 140 made of the polycrystalline silicon layer 106b is formed on the gate electrode 130.

Then, an n⁺ silicon film containing high-concentration n-type impurities is deposited by a plasma CVD method to cover the entire glass substrate 101. The film thickness of the n⁺ silicon film is, for example, 50 nm. As a raw gas for depositing the n⁺ silicon film, for example, a gas mixture of monosilane and phosphine (PH₃) containing n-type impurities such as phosphorus (P) is used. Then, the n⁺ silicon film is etched using, as a mask, a resist pattern (not shown) formed in a photolithographic process, whereby an n⁺ silicon layer 150 is formed on a surface of the polycrystalline silicon layer 106b. Then, a stacked metal film 160 in which an aluminum layer is stacked on a surface of a titanium (Ti) layer is deposited on the glass substrate 101 by a sputtering method. The film thicknesses of the respective layers of the stacked metal film 160 are, for example, such that the titanium layer is 100 nm and the aluminum layer is 300 nm.

Then, a resist pattern (not shown) is formed on a top surface of the stacked metal film 160 using a photolithography technique. The resist pattern has an opening formed at a location corresponding to the top surface of the polycrystalline silicon layer 106b. Hence, as shown in FIG. 5I, using the resist pattern as a mask, the stacked metal film 160 and the n⁺ silicon layer 150 are continuously etched by a dry etching method. As a result, both the n⁺ silicon layer 150 and the stacked metal film 160 are separated to left and right on the polycrystalline silicon layer 106b. The n⁺ silicon layers 150 separated to left and right are respectively disposed at the left and right top surface edges of the polycrystalline silicon layer 106b, as contact layers 150a and 150b. The stacked metal films 160 separated to left and right respectively serve as a source electrode 160a which is ohmic-connected to the contact layer 150a and a drain electrode 160b which is ohmic-connected to the contact layer 150b. Then, a protective film 190 made of silicon nitride is formed by a plasma CVD method to cover the TFT 100.

### 1.4 Effects

As is clear from the above description, of laser light irradiated onto the amorphous silicon layer 106a, a portion of the laser light absorbed by the amorphous silicon layer 106a is converted to heat, and thus, the amorphous silicon layer 106a is crystallized from its top surface. In addition, a portion of the laser light transmitted through the amorphous silicon layer 106a is irradiated onto the gate electrode 130 made of only the titanium layer 102. The titanium layer 102 absorbs a part of the irradiated laser light and thereby produces heat. Since the thermal conductivity of titanium is as low as 138 W/m·K, the produced heat is less likely to be dissipated from the gate electrode 130 by heat conduction and thus increases the temperature of the gate electrode 130. In addition, a part of the laser light transmitted through the amorphous silicon layer 106a is reflected by the titanium layer 102 of the gate electrode 130 and is thereby irradiated onto the bottom surface of the amorphous silicon layer 106a. By radiant heat from such a gate electrode 130 and reflection by the gate electrode 130, the bottom surface of the amorphous silicon layer 106a is heated.

As a result, the amorphous silicon layer 106a is crystallized not only from its top surface but also from its bottom surface by the radiant heat from the gate electrode 130 and the reflected laser light, turning into the polycrystalline silicon layer 106b. Hence, the grain size of grains contained in a portion of the polycrystalline silicon layer 106b near its bottom surface increases and accordingly the mobility near its bottom surface also increases. As such, since the mobility of a portion of the polycrystalline silicon layer 106b on the side of the gate electrode 130 increases, the operating speed of the TFT 100 is improved.

In addition, by using the half-tone mask 20, etching for forming the gate wiring line 110 and the gate electrode 130 and etching for removing the titanium layer 104 and aluminum layer 103 of the gate electrode 130 are performed using, as masks, the resist patterns 181 and 182 formed in a single photolithographic process. Thus, the fabrication steps can be simplified, enabling to reduce fabrication cost. In addition, the resist patterns 181 and 182 having different film thicknesses are simultaneously formed and only the resist pattern 182 is removed by oxygen plasma before the second etching. Hence, there is no need to perform layout taking into account their misalignment, enabling to reduce the area occupied by the TFT 100.

When an amorphous silicon layer of a bottom-gate type TFT is laser annealed, the percentage of reusable laser light transmitted through the amorphous silicon layer varies depending on the component material and shape of a gate electrode. For example, when a gate electrode and a gate wiring line include a layer made of a metal with a high thermal conductivity such as aluminum, heat produced in the gate electrode is transmitted through the gate wiring line and dissipated. Therefore, conventionally, since the produced heat is not accumulated in the gate electrode, the bottom surface of the amorphous silicon layer cannot be sufficiently crystallized by radiant heat from the gate electrode. In addition, since the component materials and shapes of a gate electrode and a gate wiring line vary depending on the type of a liquid crystal panel, the optimum energy of laser light needs to be changed for each of different types of liquid crystal panels. Due to this, when a plurality of types of liquid crystal panels are formed on a single glass substrate, the energy of laser light needs to be adjusted for each liquid crystal panel. However, by performing laser annealing of the TFT 100 by the aforementioned fabrication method, the percentage of reusable laser light transmitted through the amorphous silicon layer 106a significantly increases. Accordingly, even if the material and shape of the gate electrode 130 vary depending on the type of a liquid crystal panel, there is no need to adjust the energy of laser light for each liquid crystal panel, and thus, the throughput is significantly improved.

### 1.5 Variant

The above-described embodiment describes the case of forming a gate electrode 130 using a titanium layer 102 with a thermal conductivity being as low as 22 W/m·K. However, as a result of experiments conducted by the inventors of the present invention, it has been found that even when a gate electrode is formed using molybdenum (Mo) with a higher thermal conductivity (thermal conductivity: 138 W/m·K) than titanium, a TFT exhibits desired electrical characteristics. From this fact, it can be seen that the gate electrode 130 should be formed using at least a metal with a thermal conductivity of 138 W/m·K or less.

In addition, although in the above-described embodiment the gate electrode 130 has a single layer structure including only the titanium layer 102, the gate electrode 130 may have a stacked structure including a plurality of metals with a thermal conductivity of 138 W/m·K or less.

The reason that a solid laser device is used for laser annealing in the present embodiment is because it is less expensive than a gas laser and also its maintenance is easy, and thus, the fabrication cost of a TFT can be reduced. However, laser annealing may be performed using a gas laser device, instead of a solid laser device.

### 2. Second Embodiment

### 2.1 Structure of a TFT

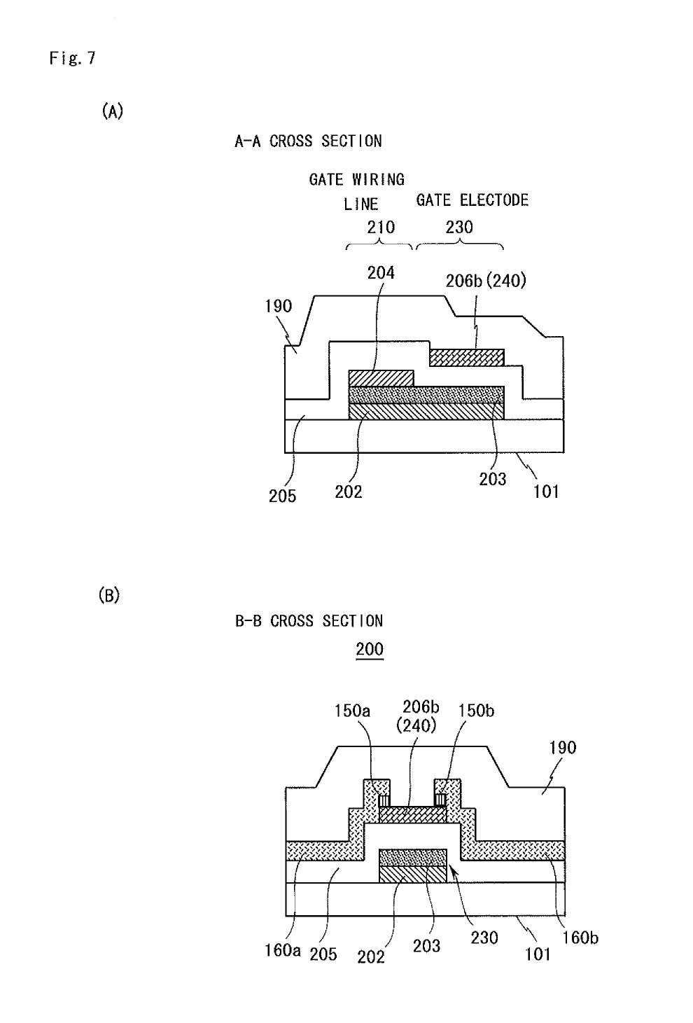

A configuration of a pixel formation portion of the present embodiment is the same as that of a pixel formation portion 10 shown in FIG. 1 and thus description thereof is omitted. FIGS. 7A and 7B are cross-sectional views of a TFT 200 according to a second embodiment of the present invention. More specifically, FIG. 7A is a cross-sectional view of the TFT 200 and a gate wiring line 210 taken along line A-A shown in FIG. 1, and FIG. 7B is a cross-sectional view of the TFT 200 taken along line B-B shown in FIG. 1. As with a TFT 100 shown in FIGS. 2A and 2B, the TFT 200 of the present embodiment is also used as a switching element in a pixel formation portion of a liquid crystal display device. Note that in the TFT 200 shown in FIGS. 7A and 7B, the same components as those of the TFT 100 shown in FIGS. 2A and 2B are denoted by the same reference numerals or corresponding reference numerals.

As with the TFT 100 shown in FIGS. 2A and 2B, in the TFT 200 according to the present embodiment, too, as shown in FIGS. 7A and 7B, a gate electrode 230 and the gate wiring line 210 are formed on a surface of a glass substrate 101. As with the TFT 100, the gate wiring line 210 has a stacked structure in which a titanium layer 202, an aluminum layer 203, and a titanium layer 204 are stacked on top of one another in succession. However, unlike the TFT 100, the gate electrode 230 has a stacked structure in which the titanium layer 202 and the aluminum layer 203 are stacked in succession on the surface of the glass substrate 101. The structure of the TFT 200 is the same as that of the TFT 100, except the gate electrode 230 and thus description thereof is omitted. Note that the titanium layer 202 of the gate wiring line 210 and the titanium layer 202 of the gate electrode 230 are the same titanium layer, and the aluminum layer 203 of the gate wiring line 210 and the aluminum layer 203 of the gate electrode 230 are the same aluminum layer.

A polycrystalline silicon layer 206b serving as a channel layer 240 is present immediately above the aluminum layer 203 of the gate electrode 230 and opposes the aluminum layer 203. The polycrystalline silicon layer 206b is formed by laser annealing an amorphous silicon layer. A detail will be described later, but using the fact that aluminum has a light reflectivity of 80% or more, most of laser light transmitted through the amorphous silicon layer is reflected by the aluminum layer 203 and is thereby irradiated onto a bottom surface of the amorphous silicon layer. As such, the amorphous silicon layer is crystallized not only from its top surface but also from its bottom surface. In this case, as with the polycrystalline silicon layer 106b of the first embodiment, not only those grains near a top surface of the polycrystalline silicon layer 206b but also those grains near its bottom surface are sufficiently large. Hence, in the polycrystalline silicon layer 206b, the mobility near its bottom surface opposing the gate electrode 230 increases, and thus, the operating speed of the TFT 200 having the polycrystalline silicon layer 206b as the channel layer 240 is improved.

### 2.2 Method of Fabricating the TFT

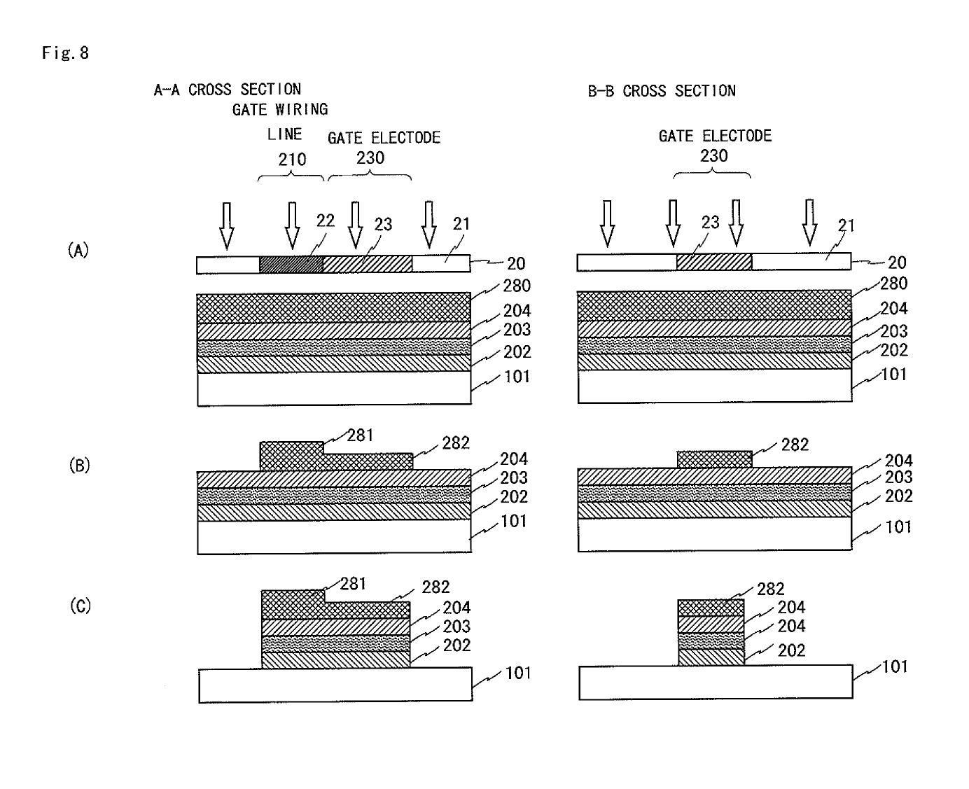

Next, a method of fabricating the TFT 200 will be described. FIGS. 8A to 8C to 10G and 10H are cross-sectional views showing the steps of fabricating the TFT 200 connected to the gate wiring line 210 in the pixel formation portion. The left diagrams in each figure are the same cross-sectional views as that of the TFT 200 and the gate wiring line 210 shown in FIG. 7A, and the right diagrams are the same cross-sectional views as that of the TFT 200 shown in FIG. 7B. A method of fabricating the TFT 200 according to the present embodiment will be described mainly for fabrication steps different than those for the TFT 100 in the first embodiment shown in FIGS. 3A to 3C to 5G to 5I.

As shown in FIG. 8A, a titanium layer 202, an aluminum layer 203, and a titanium layer 204 are continuously deposited on a surface of a glass substrate 101 in this order from the side of the glass substrate 101 by a sputtering method. Their film thicknesses are, for example, such that the titanium layer 202 is 50 nm, the aluminum layer 203 is 200 nm, and the titanium layer 204 is 50 nm. Then, a photoresist film 280 is formed on a surface of the titanium layer 204 and is exposed using a half-tone mask 20 having a predetermined pattern formed therein. Note that the half-tone mask 20 used is the same as a half-tone mask 20 used in the first embodiment and thus description thereof is omitted.

By performing exposure using the half-tone mask 20 and development, as shown in FIG. 8B, a resist pattern 282 is formed in a region where a gate electrode 230 is to be formed, and a resist pattern 281 is formed in a region where a gate wiring line 210 is to be formed. The film thickness of the resist pattern 282 is about one-half of the film thickness of the resist pattern 281.

As shown in FIG. 8C, using the resist patterns 281 and 282 as masks, etching is performed on the titanium layer 204, the aluminum layer 203, and the titanium layer 202 in this order by a dry etching method while changing gas. As a result, the gate wiring line 210 and the gate electrode 230 both have a stacked structure in which three layers, the titanium layer 202, the aluminum layer 203, and the titanium layer 204, are stacked on top of one another.

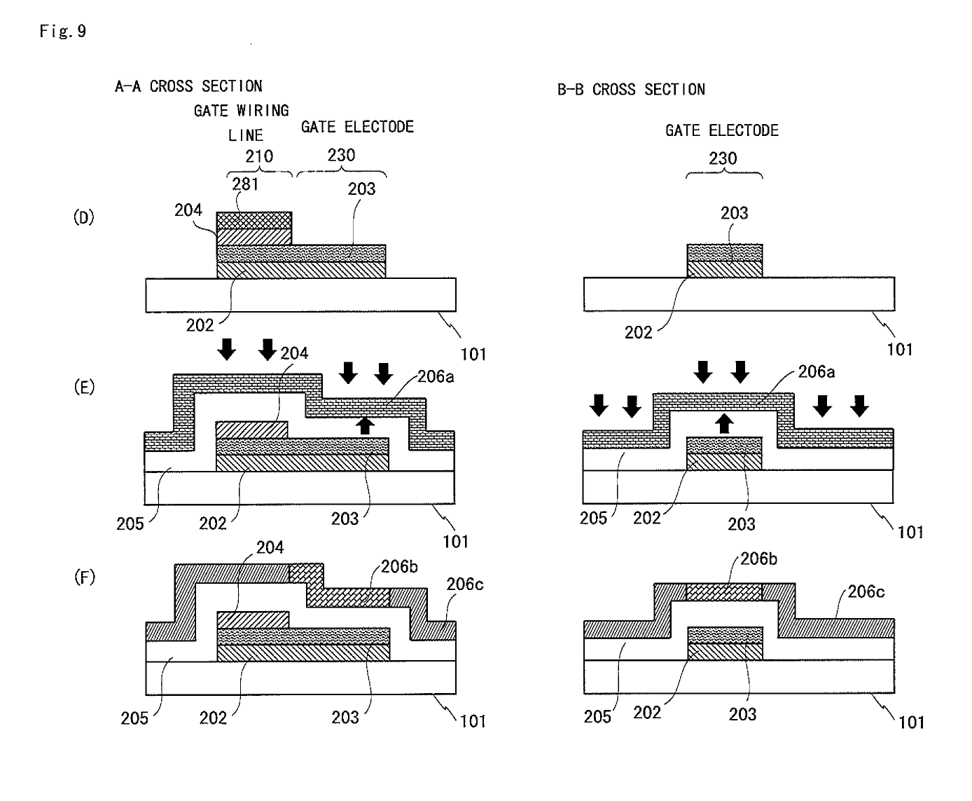

As shown in FIG. 9D, in order to expose a surface of the titanium layer 204 of the gate electrode 230, the resist pattern 282 is removed. The removal of the resist pattern 282 is performed by asking using oxygen plasma. At this time, since the resist pattern 281 on the gate wiring line 210 is also asked from its surface, its film thickness is reduced. However, since the resist pattern 281 is formed to have a larger film thickness than the resist pattern 282 in the first place, even after the resist pattern 282 is removed, the gate wiring line 210 is covered with the resist pattern 281.

Furthermore, using the remaining resist pattern 281 as a mask, the exposed titanium layer 204 of the gate electrode 230 is etched using a hydrofluoric/nitric acid-based etchant. Use of a hydrofluoric/nitric acid-based etchant enables to increase the selectivity of titanium to aluminum, and a surface of the aluminum layer 203 of the gate electrode 230 is exposed. Then, the resist pattern 281 is removed.

As shown in FIG. 9E, a silicon nitride film 205 covering the gate electrode 230 and the gate wiring line 210 is deposited by a plasma CVD method. The silicon nitride film 205 functions as a gate insulating film and its film thickness is, for example, 400 nm. Then, a non-doped amorphous silicon layer 206a is deposited on a surface of the silicon nitride film 205 by a plasma CVD method, for example, monosilane or disilane as a raw gas. The film thickness of the amorphous silicon layer 206a is, for example, 50 to 200 nm.

Laser light (green laser light) with a wavelength of 532 nm oscillated from a solid laser device is irradiated onto the amorphous silicon layer 206a. The shape and irradiation conditions of a beam are the same as those in the case of the first embodiment and thus description thereof is omitted. About 50% of the laser light irradiated onto the amorphous silicon layer 206a is absorbed by the amorphous silicon layer 206a, and the remaining about 50% is transmitted through the amorphous silicon layer 206a and the silicon nitride film 205 and is then irradiated onto the aluminum layer 203 on a surface of the gate electrode 230.

Since aluminum has a very high light reflectivity of 80% or more, most of the laser light irradiated onto the aluminum layer 203 is reflected by the aluminum layer 203 and is thereby irradiated onto a bottom surface of the amorphous silicon layer 206a. A part of the laser light irradiated onto the bottom surface of the amorphous silicon layer 206a is absorbed by the amorphous silicon layer 206a and is thereby converted to heat, and the heat crystallizes the amorphous silicon layer 206a from its bottom surface.

As such, in a region of the amorphous silicon layer 206a under which the gate electrode 230 having, on its surface, the aluminum layer 203 is provided, crystallization of the amorphous silicon layer 206a proceeds from both the top and bottom surfaces thereof, and thus, the region turns into a polycrystalline silicon layer 206b in which the grain size of grains contained not only in a portion thereof near its top surface but also in a portion thereof near its bottom surface is large. On the other hand, in a region under which such a gate electrode 230 is not provided, the amorphous silicon layer 206a is crystallized only by laser light irradiated from its top surface. Hence, crystallization near its bottom surface is insufficient, and thus, it turns into a polycrystalline silicon layer 206c in which the grain size near its bottom surface is smaller than that near its top surface.

Note that a portion of the laser light that is not reflected by the aluminum layer 203 is absorbed by the aluminum layer 203 and is thereby converted to heat and the heat is transmitted through the gate wiring line 210 and dissipated, and thus, it does not contribute to crystallization of the amorphous silicon layer 206a.

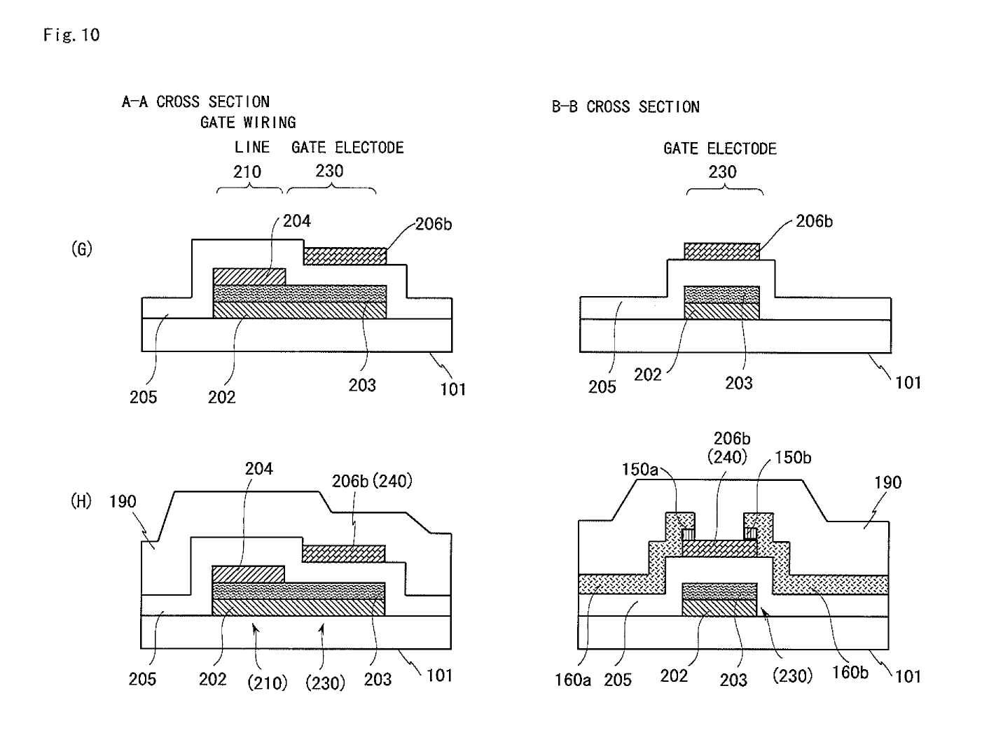

Those steps of fabricating the TFT 200 performed after the formation of the polycrystalline silicon layer 206b are, as shown in FIGS. 10G and 10H, the same as those for the TFT 100 in the first embodiment, and thus, description thereof is omitted.

### 2.3 Effects

As is clear from the above description, the aluminum layer 203 with a high light reflectivity is formed on a surface of the gate electrode 230. Hence, of laser light irradiated onto the amorphous silicon layer 206a, most of laser light transmitted through the amorphous silicon layer 206a is reflected by the aluminum layer 203 on the surface of the gate electrode 230 and is thereby irradiated onto the bottom surface of the amorphous silicon layer 206a. As such, since the amorphous silicon layer 206a is irradiated with laser light not only from its top surface but also from its bottom surface, a portion of the amorphous silicon layer 206a near its bottom surface also easily melts. As a result, the grain size of grains contained in a portion of the polycrystalline silicon layer 206b near its bottom surface also increases, and thus, the mobility near its bottom surface also increases. As such, since in the polycrystalline silicon layer 206b the mobility near its bottom surface opposing the gate electrode 230 also increases, the operating speed of the TFT 200 can be improved.

In addition, effects brought about by using the half-tone mask 20 are the same as those in the case of the first embodiment and thus description thereof is omitted.

### 2.4 Variant

In a TFT 200 according to the present embodiment, an aluminum layer 203 is exposed on a surface of a gate electrode 230. However, instead of the aluminum layer 203, a copper layer can also be used. Specifically, a gate wiring line 210 has a stacked structure in which a titanium layer, a copper layer, and a titanium layer are stacked on top of one another in this order, and a gate electrode 230 has a stacked structure in which a copper layer is stacked on a top surface of a titanium layer. The reflectivity of copper is 90% or more with respect to light with a wavelength of 600 to 800 nm, which is higher than the reflectivity of aluminum. Thus, the energy of laser light reflected by the copper layer and thereby irradiated onto a bottom surface of an amorphous silicon layer 206a is higher than the energy of laser light reflected by the aluminum layer 203 and thereby irradiated onto the bottom surface of the amorphous silicon layer 206a. Since the amorphous silicon layer 206a produces a larger amount of heat by absorbing laser light reflected by the copper layer, the crystallinity near a bottom surface of a polycrystalline silicon layer 206b further increases. In addition, since the electrical conductivity of copper is higher than that of aluminum, delay of a scanning signal on the gate wiring line 210 can be further prevented. Note that even if a silver layer is formed instead of the aluminum layer 203, the same effects can be obtained.

In particular, when laser light with a wavelength of 800 nm is irradiated onto the amorphous silicon layer 206a, the percentage of laser light transmitted through the amorphous silicon layer 206a is higher than the percentage of laser light absorbed by the amorphous silicon layer 206a. Since the laser light transmitted through the amorphous silicon layer 206a is reflected by the copper layer and is thereby irradiated onto the bottom surface of the amorphous silicon layer 206a, the crystallinity near the bottom surface of the polycrystalline silicon layer 206b further increases. In addition, since a laser device that oscillates laser light with a long wavelength, such as a wavelength of 800 nm, is less expensive than a laser device that oscillates laser light with a short wavelength and also its maintenance is easy, the fabrication cost of the TFT 200 can be reduced.

A gate electrode can employ any configuration as long as the gate electrode includes a layer made of a metal with a high light reflectivity, such as an aluminum layer 203, and thus, the configuration is not limited to that including only two layers, a titanium layer 202 and an aluminum layer 203, and the gate electrode may be formed of more layers.

In addition, by doping several percent of niobium (Nb) in an aluminum layer 203, the occurrence of microscopic projections and depressions called hillocks which occur on a surface of the aluminum layer 203 when the aluminum layer 203 is subjected to heat treatment can be suppressed. If the occurrence of such microscopic projections and depressions is suppressed, then the light reflectivity of the aluminum layer 203 further increases, enabling to further increase the energy of laser light irradiated onto the bottom surface of the amorphous silicon layer 206a.

### 3. Third Embodiment

### 3.1 Structure of a TFT

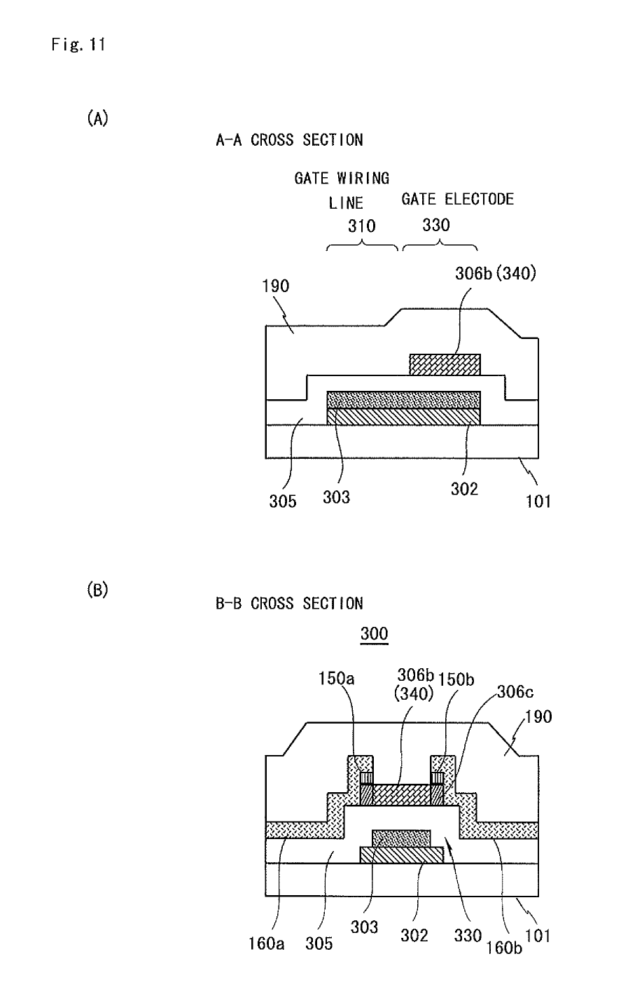

A configuration of a pixel formation portion of the present embodiment is the same as that of a pixel formation portion 10 shown in FIG. 1 and thus description thereof is omitted. FIGS. 11A and 11B are cross-sectional views showing cross-sections of a TFT 300 according to a third embodiment of the present invention. More specifically, FIG. 11A is a cross-sectional view of the TFT 300 and a gate wiring line 310 taken along line A-A shown in FIG. 1, and FIG. 11B is a cross-sectional view of the TFT 300 taken along line B-B shown in FIG. 1. As with a TFT 200 shown in FIGS. 7A and 7B, the TFT 300 of the present embodiment is also used as a switching element in a pixel formation portion of a liquid crystal display device. Note that in the TFT 300 shown in FIGS. 11A and 11B, the same components as those of the TFT 200 shown in FIGS. 7A and 7B are denoted by the same reference numerals or corresponding reference numerals.

As with the TFT 200 shown in FIGS. 7A and 7B, in the TFT 300 according to the present embodiment, too, as shown in FIGS. 11A and 11B, the gate wiring line 310 and a gate electrode 330 branching from the gate wiring line 310 are formed on a glass substrate 101. However, unlike the case of the TFT 200, in the gate electrode 330 of the TFT 300, the width of an aluminum layer 303 formed on a titanium layer 302 is narrower than that of the titanium layer 302, and moreover, the aluminum layer 303 is formed near the center of the titanium layer 302. Specifically, for example, when the width of the titanium layer 302 is 8 μm, the width of the aluminum layer 303 is 2 to 6 μm, and the width of the aluminum layer 303 is narrower than that of the titanium layer 302 by the order of 1 to 3 μm on one side and is narrower by the order of 2 to 6 μm on both sides. Also, in the gate wiring line 310, unlike a gate wiring line 210 shown in FIGS. 7A and 7B, only the aluminum layer 303 is stacked on the titanium layer 302.

A channel layer 340 is made of a non-doped first polycrystalline silicon layer 306b. Non-doped second polycrystalline silicon layers 306c are formed to sandwich the first polycrystalline silicon layer 306b from both sides, and function as offset regions. Since the first polycrystalline silicon layer 306b is present immediately above the aluminum layer 303 of the gate electrode 330, the grain size near the bottom surface of the first polycrystalline silicon layer 306b is large. On the other hand, the second polycrystalline silicon layers 306c are present immediately above the titanium layer 302 formed outside the aluminum layer 303, and thus, the grain size near the bottom surfaces of the second polycrystalline silicon layers 306c is smaller than the grain size near the bottom surface of the first polycrystalline silicon layer 306b.

As such, in the first polycrystalline silicon layer 306b, crystallization proceeds and thus the resistance value is low, and in the second polycrystalline silicon layers 306c, the resistance value is higher than that of the first polycrystalline silicon layer 306b. By providing such second polycrystalline silicon layers 306c with a high resistance value between the channel layer 340 with a low resistance value and a source electrode 160a and between the channel layer 340 and a drain electrode 160b, leakage current (off current) flowing between the source electrode 160a and the drain electrode 160b when the TFT 300 is placed in an off state (in the case of an n-channel type, a state in which a negative voltage is applied to the gate electrode 330) decreases, enabling to increase the on/off ratio. Hence, by using the TFT 300 as a switching element in the pixel formation portion, a pixel capacitance to which a voltage according to an image signal is written holds the voltage over an extended period of time and thus image deterioration is prevented. Note that the structure of the TFT 300 is the same as that of the TFT 200 shown in FIGS. 7A and 7B, except the gate electrode 330, and thus description thereof is omitted.

### 3.2 Method of Fabricating the TFT

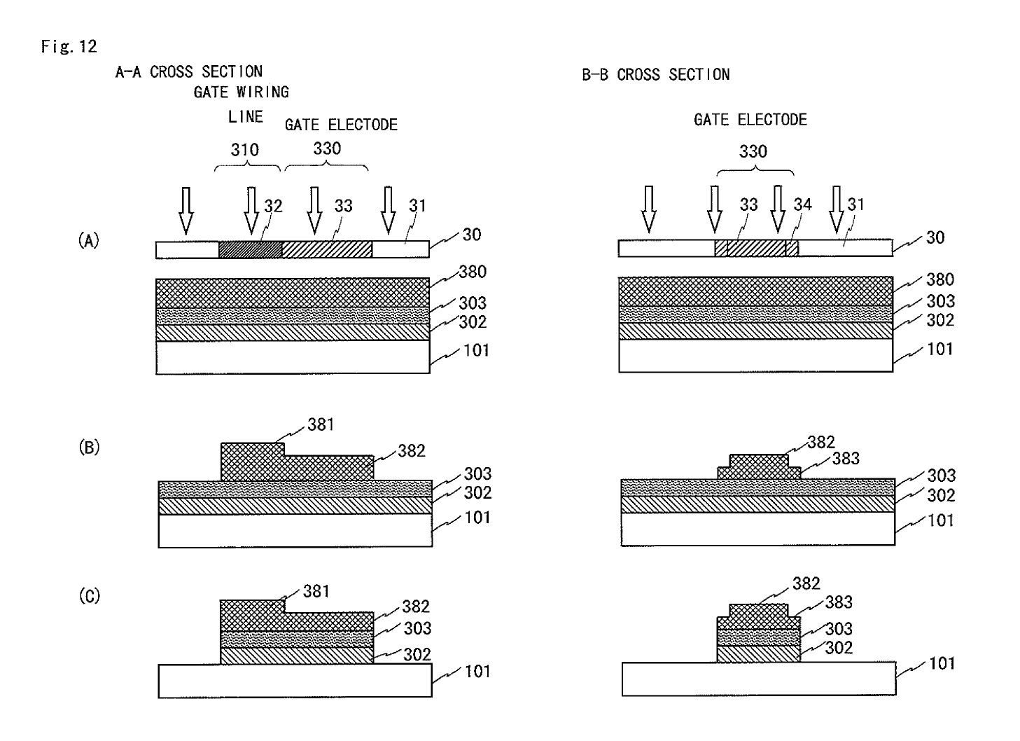

Next, a method of fabricating the TFT 300 will be described. FIGS. 12A to 12C to 15J and 15K are cross-sectional views showing the steps of fabricating the TFT 300 connected to the gate wiring line 310 in the pixel formation portion. The right diagrams in each figure are the same cross-sectional views as that of the TFT 300 and the gate wiring line 310 shown in FIG. 11A, and the left diagrams in each figure are the same cross-sectional views as that of the TFT 300 shown in FIG. 11B. A method of fabricating the TFT 300 according to the present embodiment will be described mainly for fabrication steps different than those for the TFT 200 in the second embodiment shown in FIGS. 8A to 8C to 10G and 10H.

As shown in FIG. 12A, a titanium layer 302 and an aluminum layer 303 are continuously deposited on a surface of a glass substrate 101 in this order from the side of the glass substrate 101 by a sputtering method. Their film thicknesses are, for example, such that the titanium layer 302 is 50 nm and the aluminum layer 303 is 200 nm.

Then, a photoresist film 380 is formed on a surface of the aluminum layer 303 and is exposed using a half-tone mask having a predetermined pattern formed therein. The half-tone mask 30 includes a light-shielding pattern region 32 having formed therein a light-shielding pattern which does not allow incident light to be transmitted therethrough at all; a transmission region 31 which allows incident light to be transmitted therethrough as it is; and semi-transmission pattern regions 33 and 34 having formed therein semi-transmission patterns which weaken the intensity of incident light and allow the incident light to be transmitted therethrough. In the half-tone mask 30, the pattern of a gate wiring line 310 is made of a light-shielding pattern and the pattern of a gate electrode 330 is made of two types of semi-transmission patterns having different transmittances, and a region where the titanium layer 302 and the aluminum layer 303 are all removed corresponds to the transmission region 31.

The patterns of the left and right edges of the gate electrode 330 are made of semi-transmission patterns in the semi-transmission pattern regions 34, and the pattern of a central portion of the gate electrode 330 sandwiched between the patterns of the left and right edges is made of a semi-transmission pattern in the semi-transmission pattern region 33. The semi-transmission pattern region 33 is formed such that the transmittance thereof is about ⅓ of the transmittance of the transmission region 31, and the semi-transmission pattern regions 34 are formed such that the transmittance thereof is about ⅔ of the transmittance of the transmission region 31.

As shown in FIG. 12B, by performing exposure using such a half-tone mask 30, the film thickness of a resist pattern 381 in a region where the gate wiring line 310 is to be formed is thickest, the film thickness of a resist pattern 382 in a region where the central portion of the gate electrode 330 is to be formed is about ⅔ of the film thickness of the resist pattern 381, and the film thickness of a resist pattern 383 in regions where the edges of the gate electrode 330 are to be formed is about ⅓ of the film thickness of the resist pattern 381.

As shown in FIG. 12C, using the resist patterns 381 to 383 as masks, etching is performed on the aluminum layer 303 and the titanium layer 302 in this order using a dry etching method while changing gas. As a result, the gate wiring line 310 and the gate electrode 330 both have a stacked structure in which the aluminum layer 303 is stacked on a top surface of the titanium layer 302.

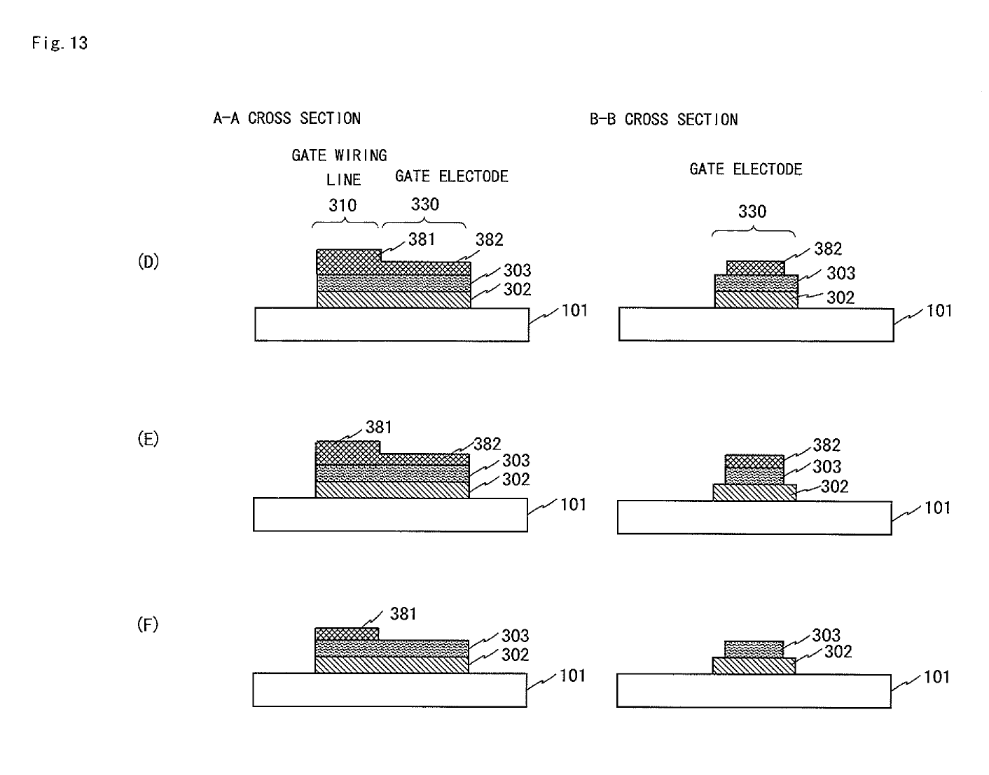

As shown in FIG. 13D, in order to expose a surface of the aluminum layer 303 at the left and right edges of the gate electrode 330, the resist pattern 383 is removed. The resist pattern 383 is removed by asking using oxygen plasma. At this time, since a part of the resist patterns 381 and 382 is also ashed, their film thicknesses are reduced. However, the resist patterns 381 and 382 are formed to have larger film thicknesses than the resist pattern 383. Thus, when the resist pattern 383 is removed, the gate wiring line 310 and the central portion of the gate electrode 330 are covered with the resist patterns 381 and 382, respectively.

As shown in FIG. 13E, using the resist patterns 381 and 382 as masks, the exposed aluminum layer 303 of the gate electrode 330 is etched using an acetic acid-based etchant. As a result, the titanium layer 302 is exposed at the left and right edges of the gate electrode 330. As shown in FIG. 13F, the resist pattern 382 is removed by asking using oxygen plasma. As a result, the aluminum layer 303 is exposed at the central portion of the gate electrode 330.

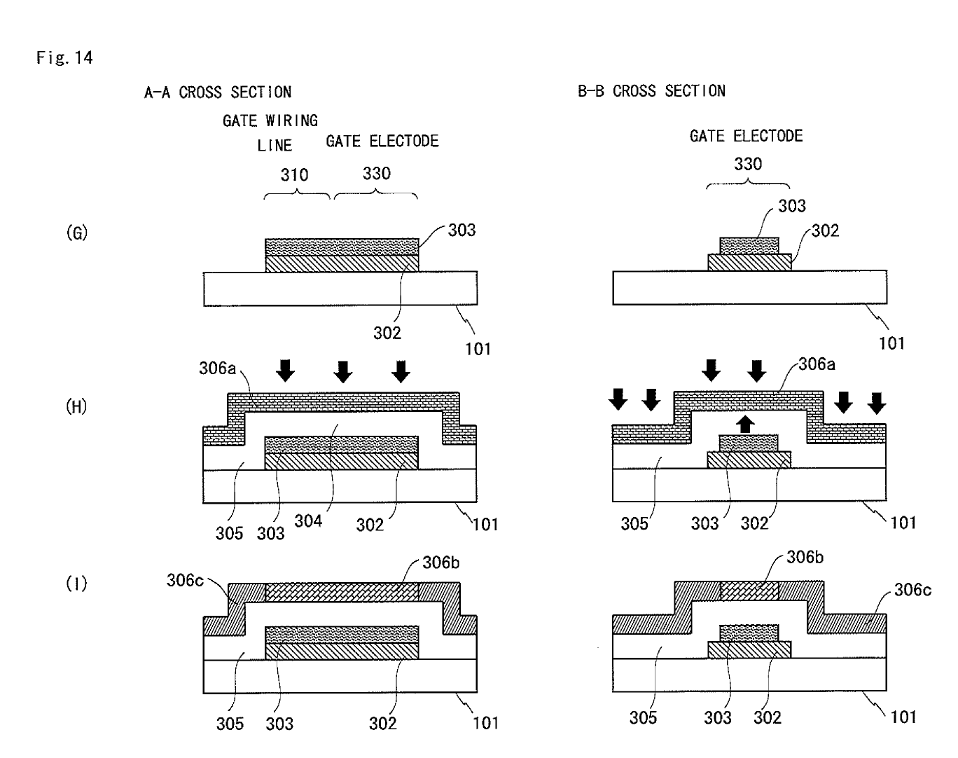

As shown in FIG. 14G, the resist pattern 381 on the gate wiring line 310 is removed. As a result, the central portion of the gate electrode 330 has a stacked structure in which the aluminum layer 303 is stacked on the top surface of the titanium layer 302, and the left and right edges of the gate electrode 330 have a single layer structure including only the titanium layer 302. Namely, the gate electrode 330 has a structure in which the titanium layer 302 protrudes to the left and right of the aluminum layer 303 in a planar view. On the other hand, the gate wiring line 310 has a stacked structure in which the aluminum layer 303 is stacked on the top surface of the titanium layer 302.

As shown in FIG. 14H, a silicon nitride film 305 serving as a gate insulating film is deposited by a plasma CVD method to cover the gate electrode 330 and the gate wiring line 310. The film thickness of the silicon nitride film 305 is, for example, 400 nm. Then, a non-doped amorphous silicon layer 306a is deposited on a surface of the silicon nitride film 305 by a plasma CVD method, for example, monosilane or disilane as a raw gas. The film thickness of the amorphous silicon layer 306a is, for example, 50 to 200 nm.

Laser light (green laser light) with a wavelength of 532 nm oscillated from a solid laser device is irradiated onto the amorphous silicon layer 306a. The shape and irradiation conditions of a beam are the same as those in the case of the first embodiment and thus description thereof is omitted. About 50% of the laser light irradiated onto the amorphous silicon layer 306a is absorbed by the amorphous silicon layer 306a, and the remaining about 50% is transmitted through the amorphous silicon layer 306a and the silicon nitride film 305 and is then irradiated onto the aluminum layer 303 on a surface of the gate electrode 330 and the exposed titanium layer 302 on the left and right thereof.

As shown in FIG. 14I, a part of the laser light transmitted through the amorphous silicon layer 306a is reflected by the aluminum layer 303 of the gate electrode 330 and is thereby irradiated onto a bottom surface of a portion of the amorphous silicon layer 306a immediately above the aluminum layer 303. Since aluminum has, as described above, a very high light reflectivity of 80% or more, most of the laser light irradiated onto the aluminum layer 303 is reflected by the aluminum layer 303 and is thereby irradiated onto the bottom surface of a portion of the amorphous silicon layer 306a opposing the aluminum layer 303. A part of the laser light irradiated onto the bottom surface of the portion of the amorphous silicon layer 306a is absorbed by the amorphous silicon layer 306a and is thereby converted to heat. As such, since the laser light reflected by the aluminum layer 303 of the gate electrode 330 is converted to heat at the bottom surface of the amorphous silicon layer 306a, crystallization also proceeds from the bottom surface. As a result, the portion of the amorphous silicon layer 306a opposing the aluminum layer 303 of the gate electrode 330 turns into a first polycrystalline silicon layer 306b with a large grain size. Therefore, the resistance value of the first polycrystalline silicon layer 306b decreases. Note that since the aluminum layer 303 is also exposed in the gate wiring line 310, as with the case of the gate electrode 330, in a portion of the amorphous silicon layer 306a opposing the gate wiring line 310, crystallization proceeds from its bottom surface.

On the other hand, a part of the laser light irradiated onto the titanium layer 302 of the gate electrode 330 is reflected by the titanium layer 302 and is thereby irradiated onto the bottom surface of the amorphous silicon layer 306a. However, since the light reflectivity of titanium is lower than that of aluminum and also the area of the titanium layer 302 onto which the laser light is irradiated is small, the degree of contribution of the reflected laser light to crystallization of the bottom surface of the amorphous silicon layer 306a is also small. Hence, in those portions of the amorphous silicon layer 306a opposing the titanium layer 302 of the gate electrode 330, crystallization from their bottom surfaces does not proceed much, and thus, the portions turn into second polycrystalline silicon layers 306c with a smaller grain size than the first polycrystalline silicon layer 306b. Therefore, the resistance value of the second polycrystalline silicon layers 306c is high. As such, the second polycrystalline silicon layers 306c with a high resistance value are formed in a self-aligned manner from those portions of the amorphous silicon layer 306a located immediately above the titanium layer 302 of the gate electrode 330.

Note that of laser light transmitted through the amorphous silicon layer 306a, a portion of the laser light that is not reflected by the aluminum layer 303 of the gate electrode 330 is absorbed by the aluminum layer 303 and is thereby converted to heat and the heat is transmitted through the gate wiring line 310 and dissipated, and thus, it does not contribute to crystallization of the amorphous silicon layer 306a. Note also that a part of laser light transmitted through the amorphous silicon layer 306a and then irradiated onto the titanium layer 302 of the gate electrode 330 is absorbed by the titanium layer 302 and is thereby converted to heat, as with the case of the first embodiment. However, since the heat produced in the titanium layer 302 of the gate electrode 330 is transmitted through the aluminum layer 303 which is in contact with the titanium layer 302, and dissipated, it does not contribute to crystallization of the amorphous silicon layer 306a.

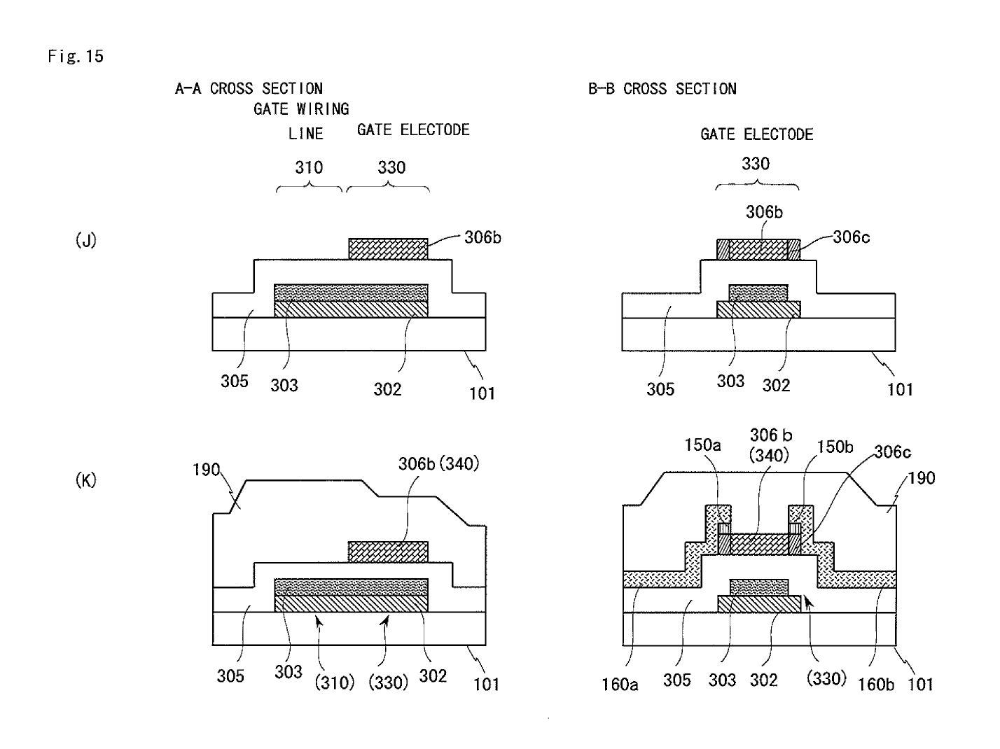

As shown in FIG. 15J, a resist pattern (not shown) is formed such that the second polycrystalline silicon layers 306c remain only immediately above those portions of the titanium layer 302 protruding from the aluminum layer 303 which forms the gate electrode 330. Then, using the resist pattern as a mask, the second polycrystalline silicon layers 306c are etched. As a result, the first polycrystalline silicon layer 306b is formed at a location on the silicon nitride film 305 opposing the aluminum layer 303 of the gate electrode 330, and the second polycrystalline silicon layers 306c are formed at locations opposing the portions of the titanium layer 302 protruding from the aluminum layer 303 of the gate electrode 330. Subsequent steps of fabricating the TFT 300 are, as shown in FIG. 15K, the same as those for a TFT 100 in the first embodiment and thus description thereof is omitted.

Note that in the present embodiment silicon layers with a high resistance value which are formed immediately above the titanium layer 302 of the gate electrode 330 in a self-aligned manner are made to serve as the second polycrystalline silicon layers 306c. However, whether the amorphous silicon layer 306a turns into polycrystalline silicon is determined by the energy of laser light irradiated onto the amorphous silicon layer 306a. When the energy is low, the amorphous silicon layer 306a remains as an amorphous silicon layer or turns into a microcrystalline silicon layer. However, in either case, the fact remains that it is a silicon layer with a high resistance value, and thus, it has the same function as the second polycrystalline silicon layers 306c.

Note also that, as with the case of the second embodiment, a copper layer or a silver layer may be formed instead of the aluminum layer 303 on the surface of the titanium layer 302. In addition, by doping several percent of niobium in the aluminum layer 303, microscopic projections and depressions may be made less likely to occur on the surface of the aluminum layer 303, thereby to increase the light reflectivity of the aluminum layer 303.

### 3.3 Effects

As is clear from the above description, most of laser light transmitted through the amorphous silicon layer 306a is reflected by the aluminum layer 303 formed on a surface of the gate electrode 330, and is thereby irradiated onto the bottom surface of the amorphous silicon layer 306a. The laser light irradiated onto the bottom surface of the amorphous silicon layer 306a is absorbed by the amorphous silicon layer 306a and is thereby converted to heat, and the heat crystallizes the amorphous silicon layer 306a from its bottom surface. Hence, in the first polycrystalline silicon layer 306b opposing the aluminum layer 303 of the gate electrode 330, the grain size increases not only near its top surface but also near its bottom surface, reducing the resistance value. On the other hand, since the light reflectivity of titanium is low, the energy of laser light reflected by the titanium layer 302 of the gate electrode 330 is low. Hence, crystallization near the bottom surfaces of the second polycrystalline silicon layers 306c opposing those portions of the titanium layer 302 protruding from the aluminum layer 303 is insufficient, increasing the resistance value. The first polycrystalline silicon layer 306b serves as the channel layer 340 of the TFT 300, and the second polycrystalline silicon layers 306c sandwiching the first polycrystalline silicon layer 306b serve as offset regions. In the TFT 300 having such a configuration, leakage current flowing when in an off-state decreases, increasing the on/off ratio.

The second polycrystalline silicon layers 306c with a high resistance value are formed in a self-aligned manner immediately above the titanium layer 302 exposed on the surface of the gate electrode 330, without forming a resist pattern. As such, there is no need to form a resist pattern which is conventionally required when offset regions are formed in a polycrystalline TFT. In this case, the steps of fabricating the TFT 300 can be simplified. In addition, since there is no need to perform layout taking into account misalignment occurring upon formation of a resist pattern, the positions of the second polycrystalline silicon layers 306c can be accurately determined and the area occupied by the TFT 300 can be reduced.

By using the half-tone mask 30, etching for forming a stacked structure of the gate electrode 330 and etching for removing those portions of the aluminum layer 303 at the left and right edges of the gate electrode 330 are performed using, as masks, the resist patterns 382 and 383 formed in a single photolithographic process. Thus, the fabrication steps can be simplified, enabling to reduce the fabrication cost of the TFT 300. In addition, the resist patterns 382 and 383 having different film thicknesses are simultaneously formed and only the resist pattern 383 is removed by oxygen plasma before the second etching. Hence, there is no need to perform layout taking into account their misalignment, enabling to reduce the area occupied by the TFT 300.

### 4. Others

### 4.1 First Variant

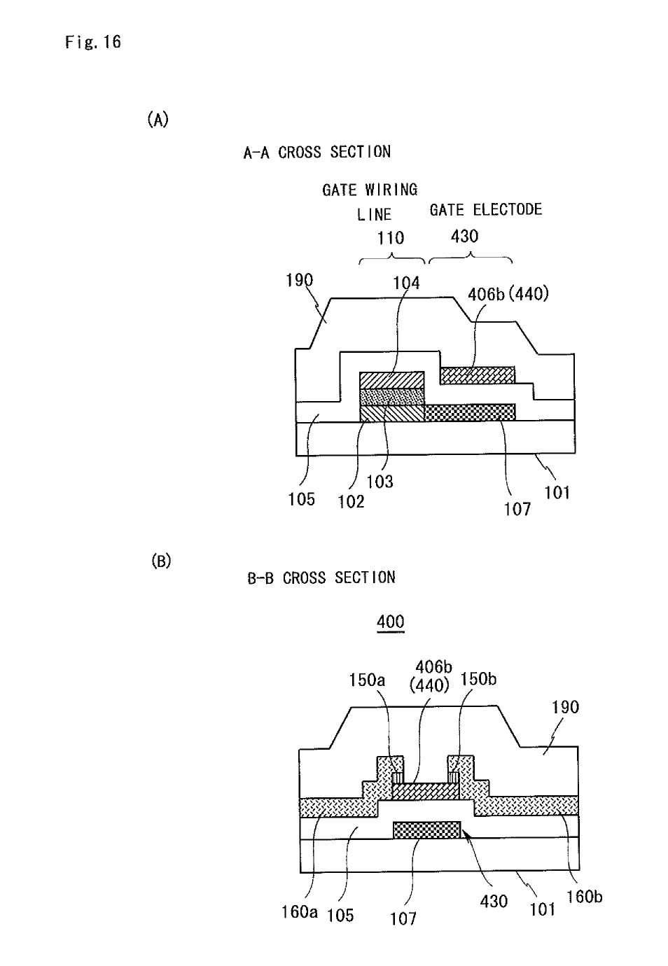

The structures of a TFT 400 according to a first variant of the present invention and a gate wiring line 110 electrically connected to the TFT 400 will be described. FIGS. 16A and 16B are cross-sectional views showing cross-sections of the TFT 400. More specifically, FIG. 16A is a cross-sectional view of the TFT 400 and the gate wiring line 110 taken along line A-A shown in FIG. 1, and FIG. 16B is a cross-sectional view of the TFT 400 taken along line B-B shown in FIG. 1. As with a TFT 100 shown in FIGS. 2A and 2B, the TFT 400 according to the present variant is also used as a switching element in a pixel formation portion of a liquid crystal display device. In the TFT 400 shown in FIGS. 16A and 16B, the same components as those of the TFT 100 shown in FIGS. 2A and 2B are denoted by the same reference numerals or corresponding reference numerals.

As with the TFT 100 shown in FIGS. 2A and 2B, the gate wiring line 110 for the TFT 400 has a stacked structure in which a titanium layer 102, an aluminum layer 103, and a titanium layer 104 are stacked on top of one another in succession. However, unlike a gate electrode 130 of the TFT 100, a gate electrode 430 is made of a transparent metal layer 107 of ITO, etc., formed on a glass substrate 101. The transparent metal layer 107 is formed in the same layer as the titanium layer 102 of the gate wiring line 110, and is electrically connected to the titanium layer 102. Furthermore, a silicon nitride film 105 serving as a gate insulating film is formed to cover the gate wiring line 110 and the gate electrode 430, and a channel layer 440 made of a polycrystalline silicon layer 406b which is obtained by laser annealing an amorphous silicon layer is formed on a surface of the silicon nitride film 105.

Unlike the case of the first to third embodiments, laser annealing of the amorphous silicon layer is performed by irradiating laser light from a backside of the glass substrate 101 (lower side in FIGS. 16A and 16B). The irradiated laser light is transmitted through the glass substrate 101, the transparent metal layer 107, and the silicon nitride film 105 and is then irradiated onto a bottom surface of the amorphous silicon layer.

In this case, as will be described later, since the laser light is irradiated onto the bottom surface of the amorphous silicon layer, the layer turns into the polycrystalline silicon layer 406b in which the grain size near the bottom surface of the amorphous silicon layer is large, and the grain size decreases as getting closer to its top surface. In addition, a film that reflects, upon laser annealing, laser light transmitted through the amorphous silicon layer is not formed above the amorphous silicon layer. Therefore, the laser light transmitted through the amorphous silicon layer cannot be reused, as the first to third embodiments do. Hence, in order to effectively utilize the irradiated laser light, it is preferable to select laser light with a wavelength at which the absorption rate of the amorphous silicon layer is high. As such laser light, for example, laser light with a wavelength of 350 to 400 nm is used.

As such, since the gate electrode 430 is formed of a transparent metal, when laser light is irradiated from the side of the glass substrate 101, the laser light is transmitted through the gate electrode 430 and is then irradiated onto the bottom surface of the amorphous silicon layer. In this case, the amorphous silicon layer melts from its bottom surface and is solidified and crystallization proceeds. Therefore, the grain size of grains contained in a portion of the polycrystalline silicon layer 406b near its bottom surface increases and accordingly the mobility near its bottom surface also increases. As such, since the mobility of a portion of the polycrystalline silicon layer 406b near its bottom surface opposing the gate electrode 430 increases, the operating speed of the TFT 400 can be improved.

### 4.2 Second Variant

In the first to third embodiments, after turning an amorphous silicon layer into a polycrystalline silicon layer by laser annealing, an n⁺ silicon film made of amorphous silicon is deposited by a plasma CVD method. However, after depositing an n⁺ silicon film, laser light may be irradiated from a top surface of the n⁺ silicon film to simultaneously crystallize the n⁺ silicon film and an amorphous silicon layer.

In this case, since not only the amorphous silicon layer but also the n⁺ silicon film is laser annealed, the n⁺ silicon film is also crystallized. Hence, the mobility of contact layers 150a and 150b formed by etching the n⁺ silicon film increases, enabling to improve the operating speed of the TFT.

Note that when laser light is irradiated onto the n⁺ silicon film, some of the n-type impurities contained in the n⁺ silicon film diffuse to a surface of a polycrystalline silicon layer sandwiched between the contact layers 150a and 150b. Hence, it is preferable that upon forming the contact layers 150a and 150b, the surface of the polycrystalline silicon layer be overetched to remove an impurity layer on the surface of the polycrystalline silicon layer.

When an etching stopper layer is formed on a top surface of the amorphous silicon layer, an n⁺ silicon film is formed to cover the amorphous silicon layer and the etching stopper layer. Hence, as with the above-described case, laser annealing of the amorphous silicon layer and the n⁺ silicon film can be simultaneously performed. In this case, the fabrication process becomes complicated. However, since some of the n-type impurities contained in the n⁺ silicon film do not diffuse to the surface of the polycrystalline silicon layer sandwiched between the contact layers 150a and 150b, there is no need to overetch the surface of the polycrystalline silicon layer upon forming the contact layers 150a and 150b.

### DESCRIPTION OF REFERENCE NUMERALS

100, 200, 300, and 400: THIN FILM TRANSISTOR (TFT)
101: GLASS SUBSTRATE
102, 202, and 302: TITANIUM LAYER
103, 203, and 303: ALUMINUM LAYER
104 and 204: TITANIUM LAYER
105: SILICON NITRIDE FILM (GATE INSULATING FILM)
106a, 206a, 306a, and 406a: AMORPHOUS SILICON LAYER
106b, 206b, 306b, and 406b: POLYCRYSTALLINE SILICON LAYER (WITH LARGE GRAIN SIZE)
106c, 206c, and 306c: POLYCRYSTALLINE SILICON LAYER (WITH SMALL GRAIN SIZE)
107: TRANSPARENT METAL LAYER
110, 210, and 310: GATE WIRING LINE
120: SOURCE WIRING LINE
130, 230, 330, and 430: GATE ELECTRODE
140, 240, 340, and 440: CHANNEL LAYER
150a and 150b: CONTACT LAYER
160a: SOURCE ELECTRODE
160b: DRAIN ELECTRODE

1. A thin film transistor comprising:
a gate electrode formed on an insulating substrate;
a gate insulating film deposited to cover the insulating substrate having formed thereon the gate electrode;
a channel layer made of a polycrystalline semiconductor layer and formed above the gate electrode with the gate insulating film therebetween, the polycrystalline semiconductor layer being crystallized by irradiating laser light onto an amorphous semiconductor layer; and
a source electrode and a drain electrode formed above the channel layer so as to be overlaid on respective top surfaces of both edges of the channel layer, wherein
at least a surface of the gate electrode is made of a material that allows crystallization of the amorphous semiconductor layer from its bottom surface using the laser light.

2. The thin film transistor according to claim 1, wherein the gate electrode includes a metal that absorbs a portion of the laser light transmitted through the amorphous semiconductor layer and thereby produces radiant heat that allows crystallization of the amorphous semiconductor layer from its bottom surface.

3. The thin film transistor according to claim 2, wherein the gate electrode includes a metal with a thermal conductivity of 138 W/m·K or less.

4. The thin film transistor according to claim 2, wherein the gate electrode includes titanium or molybdenum.

5. The thin film transistor according to claim 1, wherein at least the surface of the gate electrode is made of a metal that reflects a portion of the laser light transmitted through the amorphous semiconductor layer, as light with an intensity at which crystallization of the amorphous semiconductor layer from its bottom surface is allowed.

6. The thin film transistor according to claim 5, wherein at least the surface of the gate electrode is made of a metal with a light reflectivity of 80% or more.

7. The thin film transistor according to claim 5, wherein at least the surface of the gate electrode is made of any one of aluminum, copper, and silver.

8. The thin film transistor according to claim 1, wherein the gate electrode is made of a transparent metal.

9. The thin film transistor according to claim 6, wherein
the gate electrode includes a first layer; and a second layer formed to be located lower than the first layer, and having a larger width than the first layer,
the first layer is made of a metal with a light reflectivity of 80% or more, and
the second layer is made of a metal with a lower light reflectivity than the first layer, and protruding to left and right of the first layer in a planar view.

10. A method of fabricating a thin film transistor, the method comprising:
a gate electrode forming step of forming a gate electrode on an insulating substrate;
a gate insulating film forming step of forming a gate insulating film to cover the insulating substrate having formed thereon the gate electrode;
a laser annealing step of forming an amorphous semiconductor layer on the gate insulating film and irradiating laser light onto the amorphous semiconductor layer to turn the amorphous semiconductor layer into a polycrystalline semiconductor layer;
a channel layer forming step of forming a channel layer made of the polycrystalline semiconductor layer; and
an electrode forming step of forming a source electrode and a drain electrode formed above the channel layer so as to be overlaid on respective top surfaces of both edges of the channel layer, wherein
a wavelength of the laser light is 400 to 800 nm, and
in the laser annealing step, the amorphous semiconductor layer is crystallized from its top surface by being irradiated with the laser light and, at the same time, is crystallized from its bottom surface using a portion of the laser light transmitted through the amorphous semiconductor layer.

11. The method of fabricating a thin film transistor according to claim 10, wherein the gate electrode is formed using a metal with a thermal conductivity of 138 W/m·K or less.

12. The method of fabricating a thin film transistor according to claim 10, wherein the gate electrode is formed using a metal with a light reflectivity of 80% or more.

13. The method of fabricating a thin film transistor according to claim 12, wherein
at least a surface of the gate electrode is made of copper, and
the wavelength of the laser light is 600 to 800 nm.

14. The method of fabricating a thin film transistor according to claim 10, wherein
the thin film transistor further includes a gate wiring line connected to the gate electrode, and
the gate electrode forming step includes:
a depositing step of depositing a stacked film made of a plurality of layers including a first layer made of a metal with a light reflectivity of 80% or more;
a resist film forming step of forming a resist film on a surface of the stacked film;
a pattern forming step of forming at least a first resist pattern and a second resist pattern by performing exposure using a first half-tone mask, the first resist pattern corresponding to a pattern of the gate electrode and the second resist pattern corresponding to a pattern of the gate wiring line and having a larger film thickness than the first resist pattern;
a first etching step of etching the stacked film using the first resist pattern and the second resist pattern as masks, thereby forming a stacked element which is to become the gate electrode, and the gate wiring line;
a first pattern removing step of removing the first resist pattern by oxygen plasma;
a second etching step of etching the stacked element in turn from its surface using the second resist pattern as a mask, until a surface of the first layer is exposed; and
a second pattern removing step of removing the second resist pattern.

15. The method of fabricating a thin film transistor according to claim 14, wherein
the stacked film includes a second layer located lower than the first layer and made of a metal with a lower light reflectivity than the first layer,
in the pattern forming step, the second resist pattern corresponding to the pattern of the gate wiring line, a third resist pattern, and fourth resist patterns are formed using a second half-tone mask, the third resist pattern corresponding to a central portion of the pattern of the gate electrode and having a smaller film thickness than the second resist pattern, and the fourth resist patterns sandwiching the third resist pattern and having a smaller film thickness than the third resist pattern, and
the second etching step includes:
a third pattern removing step of removing the fourth resist patterns by oxygen plasma;
a third etching step of performing etching in turn using the second resist pattern and the third resist pattern as masks, until a surface of the second layer of the stacked element which is to become the gate electrode is exposed;
a fourth pattern removing step of removing the third resist pattern by oxygen plasma; and
a fourth etching step of performing etching in turn using the second resist pattern as a mask, until the surface of the first layer of the stacked element which is to become the gate electrode is exposed.
